(19) United States
(12) Patent Application Publication
(10) Pub. No.: US 2025/0356797 A1
(43) Pub. Date: Nov. 20, 2025

(54) Pixel Circuit and Display Device Including the Same

(71) Applicant: LG Display Co., Ltd., Seoul (KR)

(72) Inventor: Jin Yeong Kim, Paju-si (KR)

(21) Appl. No.: 19/193,170

(22) Filed: Apr. 29, 2025

(30) Foreign Application Priority Data
May 17, 2024 (KR) 10-2024-0064234

(51) Int. Cl. G09G 3/32; G09G 3/3233

(52) U.S. Cl. CPC G09G 3/32; G09G 3/3233; G09G 2300/0819; G09G 2300/0842; G09G 2300/0852; G09G 2310/08; G09G 2320/0233; G09G 2320/045; G09G 2330/10

(57) ABSTRACT

The present disclosure relates to a pixel circuit and a display device including the same. The pixel circuit may include a driving transistor for generating a current, and first and second light-emitting elements electrically connected in parallel or in series to the driving transistor. The first and second light-emitting elements may be alternately driven by the current from the driving transistor.

### CROSS-REFERENCE TO RELATED APPLICATION

This application claims priority to and the benefit of Republic of Korea Patent Application No. 10-2024-0064234 filed on May 17, 2024, which is hereby incorporated by reference in its entirety.

### BACKGROUND

### 1. Field

The present disclosure relates to a pixel circuit and a display device including the same.

### 2. Discussion of Related Art

Various flat panel display devices, such as a liquid crystal display device and an electroluminescent display device, are known. The electroluminescent display device may use light emitting elements arranged in each pixel to emit light by itself without a backlight, thereby displaying an input image. The light emitting elements of the electroluminescent display device may be divided into an organic light emitting element and an inorganic light emitting element depending on the material of a light emitting layer.

Recently, a display device that uses a light emitting diode (LED), which is an inorganic light emitting element, as a light emitting element of a pixel has attracted attention as a next-generation display device. Since the LED is made of an inorganic material, it does not require a separate encapsulation layer to protect an organic material from moisture, and it has superior reliability and long lifespan compared to an organic light emitting diode (OLED). In addition, the LED has a fast light-up speed, excellent luminous efficiency, and impact resistance.

In the case of micro LEDs, defective sub-pixels may occur due to poor transfer of micro LEDs. Without the LED binning process, micro LED chips on the wafer may be transferred to a substrate on which pixel circuits are formed by using a donor substrate. Among the micro LEDs transferred to the substrate, a contact failure may occur, or the luminance characteristics of the micro LEDs may become uneven. A defective sub-pixel identified in the electrical and optical inspection process of pixels before product shipment may become a dark spot. To remove the dark spot defect, two sub-pixels may be arranged for each color within the pixel. For example, each pixel may include two red sub-pixels, two green sub-pixels, and two blue sub-pixels. If one pixel is composed of six sub-pixels in this way, it is difficult to increase the resolution of the display panel, and transparency cannot be increased because the light transmittance is low.

### SUMMARY

The present disclosure aims to solve the above-mentioned needs and/or problems.

The present disclosure provides a pixel circuit capable of reducing dark spot defects and facilitating the implementation of a high-resolution display device and a transparent display device, and a display device including the pixel circuit.

The objectives of the present disclosure are not limited to those mentioned above, and other objectives not mentioned will be clearly understood by those skilled in the art from the description below.

A pixel circuit according to an embodiment of the present specification may include a driving transistor to generate a current; and first and second light-emitting elements electrically connected to the driving transistor in parallel or in series. The first and second light-emitting elements may be alternately driven by the current from the driving transistor.

A display device according to an embodiment of the present specification may include: a display panel on which a plurality of data lines, a plurality of gate lines, and a plurality of pixel circuits are arranged; a data driving circuit connected to the data lines; and a gate driving circuit connected to the gate lines. Each of the pixel circuits may include: a driving transistor configured to generate a current; and first and second light-emitting elements electrically connected in parallel or in series to the driving transistor. The first and second light-emitting elements may be alternately driven by the current from the driving transistor.

According to an embodiment of the present specification, it is possible to implement a pixel circuit capable of driving light-emitting elements with high efficiency and high luminance to improve their lifespan and enable low-power operation, and a display device including the same.

According to an embodiment of the present specification, by connecting two light-emitting elements to one sub-pixel in series and/or in parallel and driving the light-emitting elements alternately, the number of sub-pixels arranged in one pixel may be reduced and pixels that becomes a dark spot may be minimized or at least reduced, thereby improving process optimization and yield of the display panel.

The present disclosure may provide a pixel structure suitable for implementing a high-resolution display device and a transparent display device by minimizing or at least reducing dark spot defects and increasing the pixel density.

The effects of the present disclosure are not limited to those mentioned above, and other effects not mentioned will be clearly understood by those skilled in the art from the description of the claims.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a display device according to an embodiment of the present disclosure;

FIG. 2 is a drawing showing an example of a gate driver arranged within the display area of a display panel according to an embodiment of the present disclosure;

FIG. 3 is a drawing showing an example of a tiling display according to an embodiment of the present disclosure;

FIGS. 4A and 4B are circuit diagrams showing a pixel circuit according to a first embodiment of the present disclosure;

FIGS. 5A and 5B are circuit diagrams showing a pixel circuit according to a second embodiment of the present disclosure;

FIG. 6 is a circuit diagram showing in detail an example of the compensation circuit illustrated in FIGS. 4A and 4B according to an embodiment of the present disclosure;

FIG. 7 is a circuit diagram showing in detail an example of the compensation circuit illustrated in FIGS. 5A and 5B according to an embodiment of the present disclosure;

FIG. 8 is a waveform diagram illustrating input signals of the pixel circuits shown in FIGS. 4A to 7 according to an embodiment of the present disclosure;

FIGS. 9A and 9B are diagrams illustrating a method of alternately driving the first and second light-emitting elements in the pixel circuits shown in FIGS. 4A to 7 according to an embodiment of the present disclosure;

FIG. 10 is a circuit diagram showing a pixel circuit according to a third embodiment of the present disclosure;

FIG. 11 is a circuit diagram showing a pixel circuit according to a fourth embodiment of the present disclosure;

FIG. 12 is a circuit diagram showing in detail an example of the compensation circuit illustrated in FIG. 10 according to an embodiment of the present disclosure;

FIG. 13 is a circuit diagram showing in detail an example of the compensation circuit illustrated in FIG. 11 according to an embodiment of the present disclosure;

FIG. 14 is a waveform diagram illustrating input signals of the pixel circuits shown in FIGS. 10 to 13 according to an embodiment of the present disclosure;

FIGS. 15A and 15B are diagrams illustrating a method of alternately driving the first and second light-emitting elements in the pixel circuits shown in FIGS. 10 to 13 according to an embodiment of the present disclosure;

FIG. 16 is a circuit diagram showing a pixel circuit according to a fifth embodiment of the present disclosure;

FIG. 17 is a circuit diagram showing a pixel circuit according to a sixth embodiment of the present disclosure;

FIG. 18 is a circuit diagram showing a pixel circuit according to a seventh embodiment of the present disclosure; and

FIG. 19 is a circuit diagram showing a pixel circuit according to an eighth embodiment of the present disclosure.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present specification. Further, in describing the present disclosure, detailed descriptions of known related technologies may be omitted to avoid unnecessarily obscuring the subject matter of the present disclosure.

The terms such as “comprising,” “including,” “having,” and “containing” used herein are generally intended to allow other components to be added unless the terms are used with the term “only.” Any references to singular may include plural unless expressly stated otherwise.

Components are interpreted to include an ordinary error range even if not expressly stated.

When a positional or interconnected relationship is described between two components by using terms such as “on top of,” “above,” “below,” “next to,” “connect or couple with,” “crossing,” “intersecting,” or the like, one or more other components may be interposed between them, unless “immediately” or “directly” is used.

When a temporal antecedent relationship is described by using terms such as “after”, “following”, “next to”, “before”, or the like, it may not be continuous on a time base unless “immediately” or “directly” is used.

The terms “first,” “second,” and the like may be used to distinguish elements from each other, but the functions or structures of the elements are not limited by ordinal numbers or element names in front of the elements.

The following embodiments can be partially or entirely bonded to or combined with each other and can be linked and operated in technically various ways. The embodiments can be carried out independently of or in association with each other.

The pixel circuit of the display device may include a plurality of transistors. A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons may flow from a source to a drain. The n-channel transistor has a direction of a current flowing from the drain to the source. In the case of a p-channel transistor, since carriers are holes, a source voltage is higher than a drain voltage such that holes may flow from a source to a drain. In the p-channel transistor, since holes flow from the source to the drain, current flows from the source to the drain. It should be noted that a source and a drain of a transistor are not fixed. For example, a source and a drain may be changed according to an applied voltage. Therefore, the disclosure is not limited to a source and a drain of a transistor. In the following description, a source and a drain of a transistor will be referred to as a first electrode and a second electrode.

A gate signal swings between a gate-on voltage and a gate-off voltage. A transistor is turned on in response to a gate-on voltage and is turned off in response to a gate-off voltage. In the case of an n-channel transistor, the gate-on voltage may be a gate high voltage VGH, and the gate-off voltage may be a gate low voltage VGL. In the case of a p-channel transistor, the gate-on voltage may be the gate low voltage VGL, and the gate-off voltage may be the gate high voltage VGH.

Hereinafter, various embodiments of the present disclosure will be described in detail with reference to the accompanying drawings.

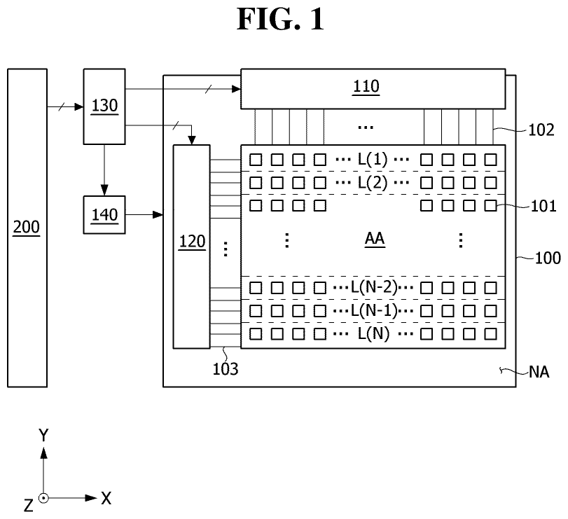

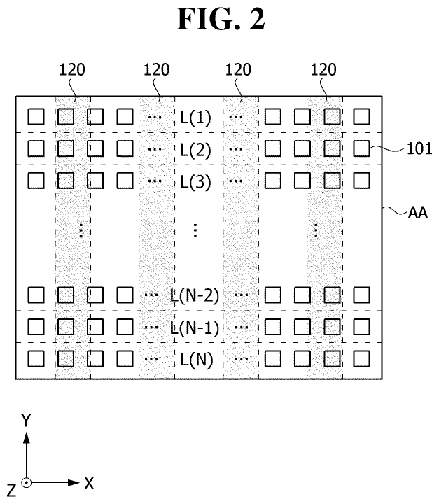

With reference to FIGS. 1 and 2, the display device according to an embodiment of the present disclosure may include a display panel 100 and a display panel driving circuit for writing pixel data to pixels of the display panel 100.

A substrate of the display panel 100 may be a plastic substrate, a thin glass substrate, or a metal substrate, but is not limited thereto. The display panel 100 may be a rectangular panel having a length in an X-axis direction (or a first direction), a width in a Y-axis direction (or a second direction), and a thickness in a Z-axis direction (or a third direction), but is not limited thereto. For example, at least a portion of the display panel 100 may have a curved perimeter.

The display panel 100 may be implemented as a non-transmissive display panel or a transmissive display panel. The transmissive display panel may be applied to a transparent display device in which an image is displayed on a screen and a real object is visible beyond the display panel. The display panel 100 may be manufactured as a flexible display panel. In addition, the display panel 100 may be manufactured as a stretchable panel that can extend.

A display area AA of the display panel 100 includes a pixel array that displays an input image. The pixel array includes a plurality of data lines 102, a plurality of gate lines 103 intersecting the data lines 102, and the pixels 101 arranged in a matrix form. The display panel 100 may further include power lines connected in common to the pixels 101. The power lines are connected in common to the pixels 101 to supply the pixels with a constant voltage required to drive the pixels 101. The power lines may be implemented as long stripe wires along the first direction or the second direction, or as mesh wires in which wires in the first direction and wires in the second direction are electrically connected.

Each of the pixels 101 may include a red sub-pixel, a green sub-pixel, and a blue sub-pixel for color implementation. In the following description, ‘pixel’ may be interpreted as ‘sub-pixel’. One sub-pixel may be arranged for each color within one pixel 101.

Each sub-pixel may include one pixel circuit, and two light-emitting elements, for example, micro LEDs, electrically connected to the pixel circuit. The pixel circuit may include an internal compensation circuit or may be connected to an external compensation circuit. When sub-pixels are connected to an external compensation circuit, the display panel 100 may further include sensing lines connected to the sub-pixels. The internal compensation circuit may be embedded in the pixel circuit of each sub-pixel to sample the threshold voltage of the driving transistor for each sub-pixel and compensate the gate-source voltage of the driving transistor by the threshold voltage. The external compensation circuit may sense the electrical characteristics of the driving transistor, such as threshold voltage and mobility, and modulate pixel data (digital data) of the input image by the deviation (or change) of the electrical characteristics of the driving transistor, thereby compensating for the electrical characteristic deviation (or change) of the driving transistor in each pixel in real time.

The pixel array includes a plurality of pixel lines L(1) to L(N). Here, N is a natural number greater than or equal to 2. Each of the pixel lines L(1) to L(N) includes one line of pixels arranged along a gate line direction (the X-axis direction) in the pixel array of the display panel 100. Pixels arranged in one pixel line may share the gate line 103. Pixels arranged in a column direction (the Y-axis direction) along a data line direction may share the same data line 102. One horizontal period is a time obtained by dividing one frame period by the total number of the pixel lines L(1) to L(N).

The display device may include a power supply omitted in FIG. 1. The power supply uses a DC-DC converter to generate a constant voltage (or a direct current (DC) voltage) required to drive the pixel array of the display panel 100 and the display panel driving circuit. The DC-DC converter may include a charge pump, a regulator, a buck converter, a boost converter, and the like. The power supply may adjust the level of an input voltage inputted from a host system 200 to output constant voltages such as a gamma reference voltage, a gate low voltage, a gate high voltage, a pixel driving voltage, and a pixel ground voltage (hereinafter referred to as “ground voltage”), a pixel reference voltage (hereinafter referred to as “reference voltage”), etc. The gamma reference voltage is supplied to a data driver 110. The dynamic range of a data voltage outputted from the data driver 110 is determined by the voltage range of the gamma reference voltage. The dynamic range of the data voltage is a voltage range between the highest grayscale voltage and the lowest grayscale voltage.

The gate high voltage and the gate low voltage are supplied to a level shifter omitted in FIG. 1 and a gate driver 120. The constant voltages, such as the pixel driving voltage, the ground voltage and the reference voltage, are supplied to the pixels 101 through the power lines connected in common to the pixels 101. The reference voltage may be interpreted as the initialization voltage. The pixel driving voltage may be supplied to the display panel 100 from a main power source of the host system 200. In this case, the power supply does not need to output the pixel driving voltage.

The display panel driving circuit writes pixel data of the input image to the pixels of the display panel 100 under the control of a timing controller 130. The display panel driving circuit includes the data driver 110 and the gate driver 120.

In at least one embodiment, the display panel driving circuit may further include a selector 140. The display panel 100 may further include a plurality of selection signal lines that supply selection signals output from the selector 140 to the sub-pixels. The selection signal lines may be commonly connected to the sub-pixels.

The display panel driving circuit may further include a touch sensor driver for driving touch sensors. The touch sensor driver is omitted in FIG. 1. The data driver 110 and the touch sensor driver may be embedded in a single drive integrated circuit (IC). The timing controller 130, power supply, level shifter, and the like may be further integrated into the drive IC.

The data driver 110 may receive pixel data of an input image as a digital signal from the timing controller 130 and output a data voltage. The data driver 110 may convert pixel data of an input image into a gamma compensation voltage by using a digital to analog converter (DAC) and output a data voltage. The gamma reference voltage may be divided through the voltage divider circuit of the data driver 110 into grayscale-specific gamma compensation voltages, which are supplied to the DAC. The DAC may generate a data voltage as a gamma compensation voltage corresponding to the grayscale value of pixel data. The data voltage output from the DAC may be output to the data lines 102 through the output buffers of the data output channels of the data driver 110.

The external compensation circuit may include a plurality of sensing channels that are embedded in the data driver 110 and convert the voltage of the sensing line into digital data and transfer it to the timing controller 130, and a compensation logic circuit embedded in the timing controller 130. Each of the sensing channels may include an analog to digital converter (ADC). The compensation logic circuit may select a compensation value based on sensing values received from the sensing channels of the data driver 110, add or multiply the selected compensation value to pixel data of an input image, and transfer the result to the data driver 110, thereby compensating for deterioration of the driving transistor and/or light-emitting elements of each sub-pixel.

The gate driver 120 may be formed in the display panel 100 together with a TFT array of the pixel array and the wires. The gate driver 120 may be disposed in the non-display area NA outside the display area AA in the display panel 100, or at least a portion thereof may be disposed in the display area AA. For example, the gate driver 120 may be embedded within a display area AA as shown in FIG. 2. In this case, the pixel circuits and light-emitting elements of the pixels 101 may overlap with the circuit of the gate driver 120 in the Z-axis direction of the display panel 100.

The gate driver 120 may be disposed in either a left non-display area NA or a right non-display area NA outside the display area AA in the display panel 100 to supply the gate signal to the gate lines 103 in a single feeding method. In the single feeding method, the gate signal is applied to one end of the gate lines. The gate driver 120 may be disposed in the left non-display area NA and the right non-display area NA in the display panel 100 to apply the gate signal to the gate lines 103 by a single feeding method or a double feeding method. In the double feeding method, the gate signal is applied simultaneously to both ends of the gate lines 103. At least some circuits of the gate driver 120 may be disposed within the display area AA.

The gate driver 120 may include a shift register and/or an edge trigger to output and shift pulses of the gate signal under the control of the timing controller 130. The gate driver 120 may output a plurality of gate signals with different waveforms. In this case, the gate driver 120 may include a plurality of gate drivers that output different gate signals. The gate signals may include a scan signal and an emission signal (referred to as “EM signal”). In this case, the gate driver 120 may include a gate driver that sequentially outputs scan signals and a gate driver that sequentially outputs EM signals.

Among the two light-emitting elements arranged in each of the sub-pixels, the light-emitting element to be driven or turned on may be selected by the output signal of the gate driver 120 or the selector 140. The gate driver 120 may output second and third EM signals for selecting the light-emitting element to be driven in each of the sub-pixels in pixel line units under the control of the timing controller 130. In this case, the gate driver 120 may further include a gate driver that sequentially outputs second EM signals and a gate driver that sequentially outputs third EM signals.

The selector 140 may select a light-emitting element to be driven or turned on among the two light-emitting elements arranged in each of the sub-pixels in a global manner for the whole display area AA under the control of the timing controller 130.

The timing controller 130 receives the pixel data of the input image and a timing signal synchronized with the pixel data from the host system 200. The timing signal may include a vertical synchronization signal Vsync, a horizontal synchronization signal Hsync, and a data enable signal DE. The vertical sync signal Vsync indicates one frame period including a pulse generated once every frame period. Pulses of the horizontal synchronization signal Hsync and the data enable signal DE may be one horizontal period (1H). The timing controller 130 may determine one frame period (or vertical period) and a horizontal period by counting the data enable signal DE. In this case, the vertical synchronization signal Vsync and the horizontal synchronization signal Hsync may be omitted. The timing controller 130 may determine which frame period the current frame period is by counting the rising edge or falling edge of the pulses in the start pulse of the timing signal Vsync, Hsync, and DE or a gate timing signal.

The timing controller 130 may control the gate driver 120 or the selector 140 based on the sub-pixel map data in which the location information of the light-emitting elements determined to be defective in the inspection process among the first and second light-emitting elements arranged in each of the sub-pixels is set. The sub-pixel map data may be stored in the memory accessed by the timing controller 130. A sub-pixel becomes a dark spot when both light-emitting elements arranged in the corresponding sub-pixel are defective, and the sub-pixel may be driven normally if any one of the light-emitting elements can be driven.

The timing controller 130 may control the operation timing of the data driver 110, the gate driver 120, and the selector 140 based on the timing signals Vsync, Hsync and DE received from the host system 200. The timing control signal output from the timing controller 130 may be supplied to the gate driver 120 and/or the selector 140 through the level shifter.

The host system 200 may scale an image signal from a video source to match the resolution of the display panel 100 and may transmit it to the timing controller 130 together with the timing control signal.

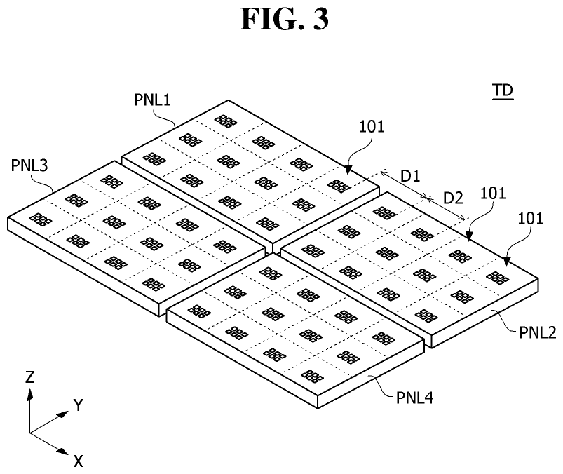

The display device may be implemented as a tiled display (TD) in which a plurality of display panels are combined in the same plane to provide a wide-screen, as shown in FIG. 3.

Referring to FIG. 3, a wide-screen tiled display TD includes a plurality of display panels PNL1 to PNL4 disposed on a X-Y plane. When the non-display area NA is minimized at the outer periphery of each display panel PNL1 to PNL4, a wide-screen image may be reproduced with no visible seams between adjacent display panels PNL1 to PNL4. The gate driver 120 may be embedded in the display area AA of the display panels PNL1 to PNL4 such that the outer periphery non-display area NA of the display panels PNL1 to PNL4 may be minimized.

The display panels 100 may be assembled on a plane such that the distance D1 between the outermost pixels 101 adjacent at the boundaries between adjacent display panels PNL1 to PNL4 is substantially the same as the distance D2 between adjacent pixels 101 within the display area AA of each of the display panels PNL1 to PNL4. As a result, the distances D1 and D2 between the pixels 101 are the same throughout the wide-screen display area of the tiled display device TD, and thus a seam region is not visible.

In the following description, the first selection signal and the second EM signal may be interpreted as a first control signal. The second selection signal and the third EM signal may be interpreted as a second control signal.

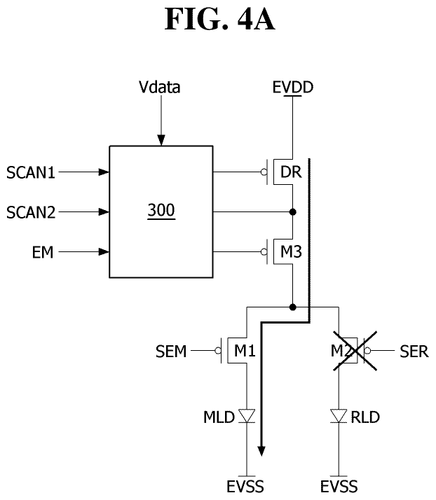

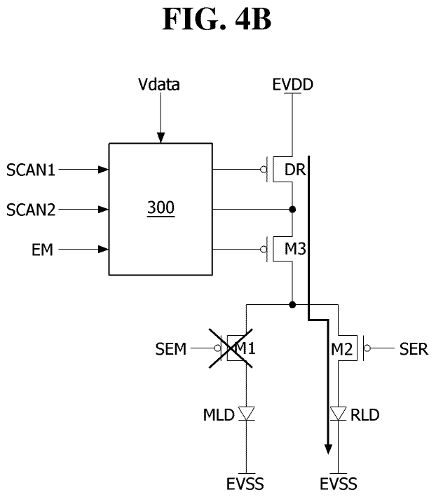

FIGS. 4A and 4B are circuit diagrams showing a pixel circuit according to a first embodiment of the present disclosure.

Referring to FIGS. 4A and 4B, the pixel circuit may include a first light-emitting element MLD, a second light-emitting element RLD, a driving transistor DR, a plurality of switch transistors M1, M2, and M3, and a compensation circuit 300. The driving transistor DR and the switch transistors M1, M2, and M3 may be implemented with, but not limited to, p-channel transistors.

Each of the first and second light-emitting elements MLD and RLD may include an anode electrode, a cathode electrode, and an emission layer. The light-emitting elements MLD and RLD may be light-emitting elements such as, but not limited to, OLEDs and micro LEDs. Micro LED chips may be implemented in a lateral structure or a flip chip structure. One of the first and second light-emitting elements MLD and RLD may be interpreted as a main light-emitting element, and the other may be interpreted as a redundant light-emitting element.

The first and second light-emitting elements MLD and RLD may be connected in parallel to the driving transistor DR through the switch transistors M1, M2 and M3. The driving transistor DR generates a current for driving the first and second light-emitting elements MLD and RLD according to the gate-source voltage. The gate-source voltage of the driving transistor DR may vary according to the data voltage Vdata of pixel data applied to the gate electrode of the driving transistor DR. Hence, the current flowing through the driving transistor DR may change according to the data voltage Vdata. The light-emitting elements MLD and RLD may be driven to emit light by the current from the driving transistor DR. The driving transistor DR may include a gate electrode to which the data voltage Vdata is applied, a first electrode to which the pixel driving voltage EVDD is applied, and a second electrode connected to the first electrode of the third switch transistor M3.

The first switch transistor M1 may be connected between the third switch transistor M3 and the anode electrode of the first light-emitting element MLD. The first switch transistor M1 may be turned on in response to a gate-on voltage of the first selection signal SEM, for example, a gate low voltage VGL, and may be turned off in response to a gate-off voltage of the first selection signal SEM, for example, a gate high voltage VGH. When the first switch transistor M1 and the third switch transistor M3 are turned on, the first light-emitting element MLD may be electrically connected to the driving transistor DR as shown in FIG. 4A, so that the first light-emitting element MLD may be driven.

The second switch transistor M2 may be connected between the third switch transistor M3 and the anode electrode of the second light-emitting element RLD. The second switch transistor M2 may be turned on in response to the gate-on voltage of the second selection signal SER, and may be turned off in response to the gate-off voltage of the second selection signal SER. When the second switch transistor M2 and the third switch transistor M3 are turned on, the second light-emitting element RLD may be electrically connected to the driving transistor DR as shown in FIG. 4B, so that the second light-emitting element RLD may be driven.

The third switch transistor M3 may be connected between the driving transistor DR and the first and second switch transistors M1 and M2. The third switch transistor M3 may be turned on in response to the gate-on voltage of the EM signal EM and may be turned off in response to the gate-off voltage of the EM signal EM. When the third switch transistor M3 is turned on, the driving transistor DR may be electrically connected to the first or second switch transistor M1 or M2.

The compensation circuit 300 may be connected to the data line to which the data voltage Vdata is applied and the gate lines to which the gate signals SCAN1, SCAN2 and EM are applied. The compensation circuit 300 may include a plurality of transistors and one or more capacitors. The compensation circuit 300 may transfer the data voltage Vdata to the gate electrode of the driving transistor DR. The compensation circuit 300 may sample the threshold voltage of the driving transistor DR at the capacitor and compensate for the gate voltage of the driving transistor DR by the threshold voltage of the driving transistor DR.

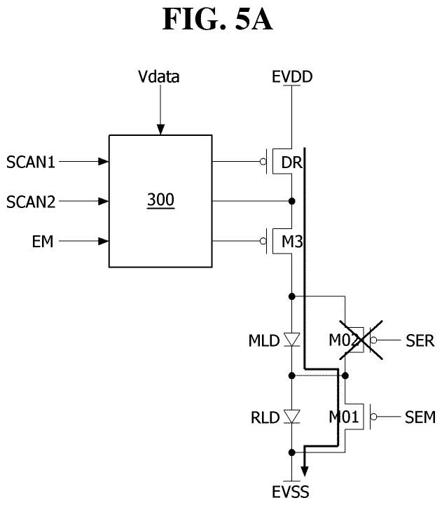

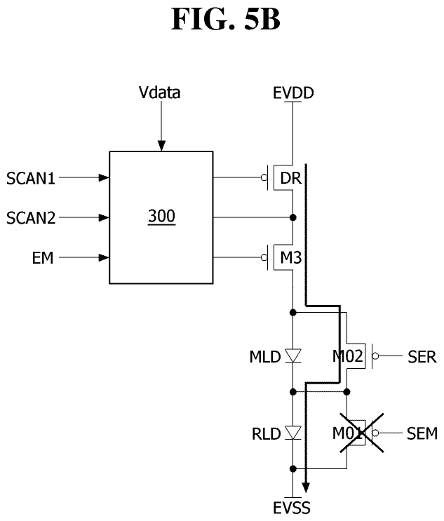

FIGS. 5A and 5B are circuit diagrams showing a pixel circuit according to a second embodiment of the present disclosure. In this embodiment, descriptions identical to those of the first embodiment described above will be omitted.

Referring to FIGS. 5A and 5B, the driving transistor DR, the third switch transistor M3, the first light-emitting element MLD, and the second light-emitting element RLD may be connected in series between the pixel driving voltage EVDD and the ground voltage EVSS.

The first light-emitting element MLD may include an anode electrode connected to the second electrode of the third switch transistor M3, and a cathode electrode connected to the anode electrode of the second light-emitting element RLD. The second light-emitting element RLD may include an anode electrode connected to the cathode electrode of the first light-emitting element MLD, and a cathode electrode to which the ground voltage EVSS is applied.

The first switch transistor M01 may be connected between both ends of the second light-emitting element RLD. The first switch transistor M01 may be turned on in response to the gate-on voltage of the first selection signal SEM, and may be turned off in response to the gate-off voltage of the first selection signal SEM. When the first switch transistor M01 is turned on, both ends of the second light-emitting element RLD may be short-circuited. At this time, as shown in FIG. 5A, a current from the driving transistor DR flows to the first light-emitting element MLD so that the first light-emitting element MLD can be driven, while the second light-emitting element RLD is in the off state with both ends short-circuited.

The second switch transistor M02 may be connected between both ends of the first light-emitting element MLD. The second switch transistor M02 may be turned on in response to the gate-on voltage of the second selection signal SER, and may be turned off in response to the gate-off voltage of the second selection signal SER. When the second switch transistor M02 is turned on, the both ends of the first light-emitting element MLD may be short-circuited. At this time, as shown in FIG. 5B, a current from the driving transistor DR flows to the second light-emitting element RLD so that the second light-emitting element RLD can be driven, while the first light-emitting element MLD is in the off state with both ends short-circuited.

The third switch transistor M3 may be turned on in response to the gate-on voltage of the EM signal EM and may be turned off in response to the gate-off voltage of the EM signal EM. When the third switch transistor M3 is turned on, the second electrode of the driving transistor DR may be electrically connected to the anode electrode of the first light-emitting element MLD. The third switch transistor M3 may include a gate electrode to which the EM signal is applied, a first electrode connected to the second electrode of the driving transistor DR, and a second electrode connected to the anode electrode of the first light-emitting element MLD and the first electrode of the second switch transistor M02.

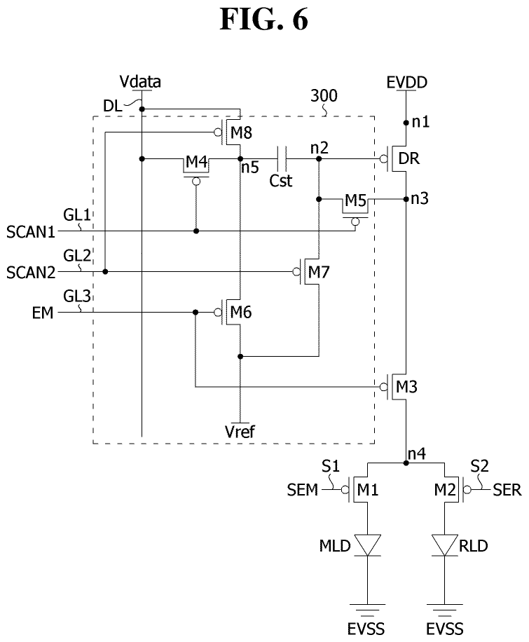

FIG. 6 is a circuit diagram showing in detail an example of the compensation circuit illustrated in FIGS. 4A and 4B according to an embodiment of the present disclosure.

Referring to FIG. 6, a pixel driving voltage EVDD, a ground voltage EVSS, and a reference voltage Vref may be applied to the pixel circuit. The pixel driving voltage EVDD, the ground voltage EVSS, and the reference voltage Vref may be set, but not limited, to 10 V, 0 V, and 2 V, respectively.

The data voltage Vdata, gate signals SCAN1, SCAN2, and EM, and selection signals SEM and SER may be input to the pixel circuit. The data voltage Vdata may be a voltage with a dynamic range between 0 V and 10 V, without being limited thereto. For the gate signals SCAN1, SCAN2 and EM and the selection signals SEM and SER, the gate high voltage VGH and the gate low voltage VGL may be set, but not limited, to 15 V and −8 V, respectively.

The driving transistor DR may include a first electrode connected to a first node n1, a gate electrode connected to a second node n2, and a second electrode connected to a third node n3. The first node n1 may be connected to the power line to which the pixel driving voltage EVDD is applied.

The first switch transistor M1 may include a first electrode connected to a fourth node n4, a gate electrode connected to a first selection signal line S1 to which the first selection signal SEM is applied, and a second electrode connected to the anode electrode of the first light-emitting element MLD. The second switch transistor M2 may include a first electrode connected to the fourth node n4, a gate electrode connected to a second selection signal line S2 to which the second selection signal SER is applied, and a second electrode connected to the anode electrode of the second light-emitting element RLD.

The first light-emitting element MLD may include an anode electrode connected to the second electrode of the first switch transistor M1, and a cathode electrode connected to the power line to which the ground voltage EVSS is applied. The second light-emitting element RLD may include an anode electrode connected to the second electrode of the second switch transistor M2, and a cathode electrode connected to the power line to which the ground voltage EVSS is applied.

The third switch transistor M3 may include a first electrode connected to the third node n3, a gate electrode connected to the third gate line GL3 to which the EM signal EM is applied, and a second electrode connected to the fourth node n4.

The compensation circuit 300 may include a capacitor Cst and a fourth switch transistor M4 to an eighth switch transistor M8.

The capacitor Cst may be connected between the second node n2 and the fifth node n5 to suppress variation of the gate-source voltage of the driving transistor DR until the next data voltage is input. For example, the gate-source voltage of the driving transistor DR may be maintained by the capacitor Cst for approximately one frame period.

The fourth switch transistor M4 may be connected between the data line DL to which the data voltage Vdata is applied and the fifth node n5. The data voltage Vdata is output from the data driver 110. The fourth switch transistor M4 may be turned on in response to the gate low voltage VGL of the first scan signal SCAN1 and may be turned off in response to the gate high voltage VGH of the first scan signal SCAN1. When the fourth switch transistor M4 is turned on, the data line DL may be electrically connected to the fifth node n5. The fourth switch transistor M4 may include a first electrode connected to the data line DL, a gate electrode connected to the first gate line GL1 to which the first scan signal SCAN1 is applied, and a second electrode connected to the fifth node n5.

The fifth switch transistor M5 may be connected between the second node n2 and the third node n3. The fifth switch transistor M5 may be turned on in response to the gate low voltage VGL of the first scan signal SCAN1 and may be turned off in response to the gate high voltage VGH of the first scan signal SCAN1. When the fifth switch transistor M5 is turned on, the second node n2 may be electrically connected to the third node n3. The fifth switch transistor M5 may include a first electrode connected to the second node n2, a gate electrode connected to the first gate line GL1, and a second electrode connected to the third node n3.

The sixth switch transistor M6 may be connected between the power line to which the reference voltage Vref is applied and the fifth node n5. The sixth switch transistor M6 may be turned on in response to the gate low voltage VGL of the EM signal EM and may be turned off in response to the gate high voltage VGH of the EM signal EM. When the sixth switch transistor M6 is turned on, the reference voltage Vref may be applied to the fifth node n5. The sixth switch transistor M6 may include a first electrode connected to the fifth node n5, a gate electrode connected to the third gate line GL3 to which the EM signal EM is applied, and a second electrode to which the reference voltage Vref is applied.

The seventh switch transistor M7 may be connected between the second node n2 and the power line to which the reference voltage Vref is applied. The seventh switch transistor M7 may be turned on in response to the gate low voltage VGL of the second scan signal SCAN2 and may be turned off in response to the gate high voltage VGH of the second scan signal SCAN2. When the seventh switch transistor M7 is turned on, the reference voltage Vref may be applied to the second node n2. The seventh switch transistor M7 may include a first electrode connected to the second node n2, a gate electrode connected to the second gate line GL2 to which the second scan signal SCAN2 is applied, and a second electrode to which the reference voltage Vref is applied.

The eighth switch transistor M8 may be connected between the data line DL to which the data voltage Vdata is applied and the fifth node n5. The eighth switch transistor M8 may be turned on in response to the gate low voltage VGL of the second scan signal SCAN2 and may be turned off in response to the gate high voltage VGH of the second scan signal SCAN2. When the eighth switch transistor M8 is turned on, the data line DL may be electrically connected to the fifth node n5. The eighth switch transistor M8 may include a first electrode connected to the data line DL, a gate electrode connected to the second gate line GL2, and a second electrode connected to the fifth node n5.

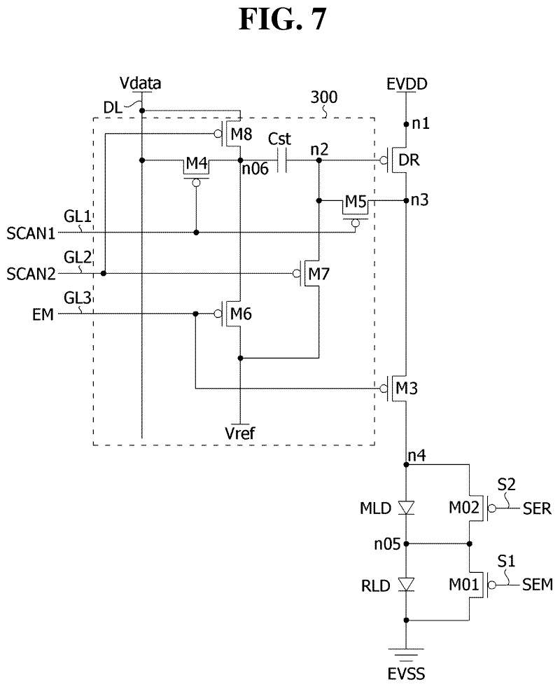

FIG. 7 is a circuit diagram showing in detail an example of the compensation circuit illustrated in FIGS. 5A and 5B according to an embodiment of the present disclosure. In this embodiment, descriptions that are substantially the same as or overlapping with those of the embodiments shown in FIGS. 5A to 6 will be omitted.

Referring to FIG. 7, the driving transistor DR may include a first electrode connected to the first node n1, a gate electrode connected to the second node n2, and a second electrode connected to the third node n3.

The first light-emitting element MLD may include an anode electrode connected to the fourth node n4 and a cathode electrode connected to the fifth node n05. The second light-emitting element RLD may include an anode electrode connected to the fifth node n05 and a cathode electrode connected to the power line to which the ground voltage EVSS is applied.

The first switch transistor M01 may include a first electrode connected to the fifth node n05, a gate electrode connected to the first selection signal line S1 to which the first selection signal SEM is applied, and a second electrode connected to the cathode electrode of the second light-emitting element RLD. The second switch transistor M02 may include a first electrode connected to the fourth node n4, a gate electrode connected to the second selection signal line S2 to which the second selection signal SER is applied, and a second electrode connected to the fifth node n5.

The third switch transistor M3 may include a first electrode connected to the third node n3, a gate electrode connected to the third gate line GL3 to which the EM signal EM is applied, and a second electrode connected to the fourth node n4.

The capacitor Cst may be connected between the second node n2 and the sixth node n06. The fourth switch transistor M4 may be connected between the data line DL to which the data voltage Vdata is applied and the sixth node n06. When the fourth switch transistor M4 is turned on, the data line DL may be electrically connected to the sixth node n06. The fourth switch transistor M4 may include a first electrode connected to the data line DL, a gate electrode connected to the first gate line GL1 to which the first scan signal SCAN1 is applied, and a second electrode connected to the sixth node n06.

The fifth switch transistor M5 may be connected between the second node n2 and the third node n3. When the fifth switch transistor M5 is turned on, the second node n2 may be electrically connected to the third node n3.

The sixth switch transistor M6 may be connected between the power line to which the reference voltage Vref is applied and the sixth node n06. When the sixth switch transistor M6 is turned on, the reference voltage Vref may be applied to the sixth node n06. The sixth switch transistor M6 may include a first electrode connected to the sixth node n06, a gate electrode connected to the third gate line GL3 to which the EM signal EM is applied, and a second electrode to which the reference voltage Vref is applied.

The seventh switch transistor M7 may be connected between the second node n2 and the power line to which the reference voltage Vref is applied. When the seventh switch transistor M7 is turned on, the reference voltage Vref may be applied to the second node n2.

The eighth switch transistor M8 may be connected between the data line DL and the sixth node n06. When the eighth switch transistor M8 is turned on, the data line DL may be electrically connected to the sixth node n06. The eighth switch transistor M8 may include a first electrode connected to the data line DL, a gate electrode connected to the second gate line GL2, and a second electrode connected to the sixth node n06.

The pixel circuits illustrated in FIGS. 4A to 7 may be driven in initialization, sampling, holding, and emission phases during one frame period.

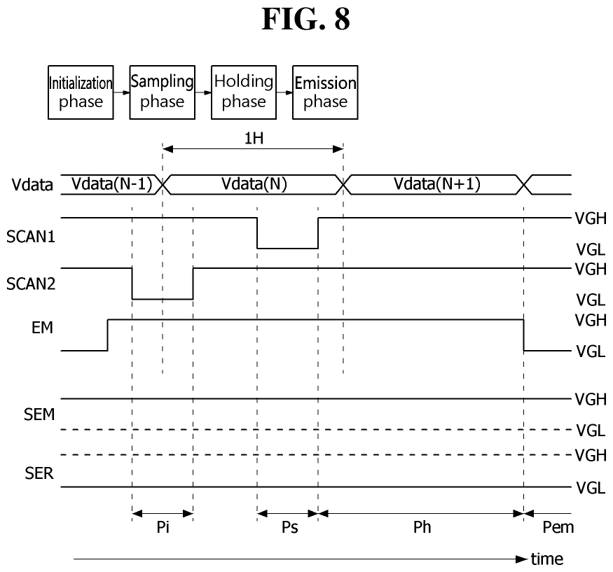

FIG. 8 is a waveform diagram illustrating input signals of the pixel circuits shown in FIGS. 4A to 7 according to an embodiment of the present disclosure.

Referring to FIGS. 6 to 8, the initialization phase may be performed during a first period Pi. During the first period Pi, the voltage of the second scan signal SCAN2 is the gate low voltage VGL, and the voltages of the first scan signal SCAN1 and the EM signal EM are the gate high voltage VGH. Hence, during the first period Pi, the seventh and eighth switch transistors M7 and M8 may be turned on, while the third to sixth switch transistors M3 to M6 may be in the off state. During the first period Pi, the first and second switch transistors M1, M01, M2 and M02 may be turned on according to the voltages of the first and second selection signals SEM and SER, but the light-emitting elements MLD and RLD do not emit light because the third switch transistor M3 are in the off state.

During the first period Pi, the reference voltage Vref may be applied to the second node n2, so that the gate voltage of the driving transistor DR may be initialized to the reference voltage Vref.

During the first period Pi, the data voltage Vdata(N−1) of the previous pixel line, for example, the N−1^{th} pixel line, may be applied to the data line DL, and then the data voltage Vdata(N) of the current pixel line may be applied to the data line DL. The data voltage Vdata(N) may be applied through the eighth switch transistor M8 to the fifth node n5 illustrated in FIG. 6 and the sixth node n06 illustrated in FIG. 7.

The sampling phase may be performed during a second period Ps. During the second period Ps, the voltage of the first scan signal SCAN1 is the gate low voltage VGL, and the voltages of the second scan signal SCAN2 and the EM signal EM are the gate high voltage VGH. Hence, during the second period Ps, the fourth switch transistor M4 and the fifth switch transistor M5 may be turned on, while the third switch transistor M3 and the sixth to eighth switch transistors M6 to M8 may be in the off state. During the second period Ps, the first and second switch transistors M1, M01, M2 and M02 may be turned on according to the voltages of the first and second selection signals SEM and SER, but the light-emitting elements MLD and RLD do not emit light because the third switch transistor M3 is in the off state.

The driving transistor DR may be in the on state when entering the second period Ps and may be turned off when reaching the off condition (Vs−Vg)+Vth<0. Here, Vs−Vg is the difference voltage between the voltage Vs of the first node n1 and the voltage Vg of the second node n2. At the end of the second period Ps, the voltage of the second node n2 may be EVDD+Vth. At the end of the second period Ps, the voltages of the fifth node n5 illustrated in FIG. 6 and the sixth node n06 illustrated in FIG. 7 may be the data voltage Vdata(N). Therefore, in the second period Ps, the data voltage Vdata(N) compensated by the threshold voltage Vth of the driving transistor DR may be stored in the capacitor Cst.

Meanwhile, after the eighth switch transistor M8 is turned on and the data line DL is connected to the fifth node n5 illustrated in FIG. 6 or the sixth node n06 illustrated in FIG. 7, the fourth switch transistor M4 may be turned on and the data line DL may be connected to the fifth node n5 illustrated in FIG. 6 or the sixth node n06 illustrated in FIG. 7. For example, the eighth switch transistor M8 may apply the same data voltage Vdata(N) as the data voltage Vdata(N) applied to the node n5 or n06 connected to one electrode of the capacitor Cst during the sampling phase to the node n5 or n06 during the initialization phase, thereby preventing the driving transistor DR from being not driven during the sampling phase or a threshold voltage sampling error. If the eighth switch transistor M8 is not present, the voltage of the node n5 or n06 connected to one electrode of the capacitor Cst may vary depending on the previous state during the sampling phase, which may increase the voltage of the second node n2 through capacitor coupling, so the driving transistor DR may be not driven normally.

The holding phase may be performed during a third period Ph. During the third period Ph, the voltages of the first scan signal SCAN1, the second scan signal SCAN2 and the EM signal EM may be the gate high voltage VGH. Hence, during the third period Ph, the voltage of the capacitor Cst remains at its previous state.

The emission phase may be performed during a fourth period Pem. During the fourth period Pem, the voltage of the EM signal EM may be the gate low voltage VGL, and the voltages of the first scan signal SCAN1 and the second scan signal SCAN2 may be the gate high voltage VGH. Hence, during the fourth period Pem, the third and sixth switch transistors M3 and M6 may be turned on, while the fourth switch transistor M4, the fifth switch transistor M5, the seventh switch transistor M7, and the eighth switch transistor M8 may be in the off state. During the fourth period Pem, the driving transistor DR may generate a current according to the gate-source voltage, and the light-emitting elements MLD and RLD selected according to the selection signals SEM and SER may be alternately driven.

During the fourth period Pem, the voltage of the fifth node n5 illustrated in FIG. 6 and the sixth node n06 illustrated in FIG. 7 may be changed to the reference voltage Vref, and the voltage of the second node n2 being floating may be changed by the amount of this voltage change. During the fourth period Pem, the current (I_{ds}) flowing through the light-emitting elements MLD and RLD being driven is as follows.

$$\begin{matrix}{I}_{ds} = \frac{1}{2} μ {C}_{o x} \frac{W}{L} {( Vgs + Vth )}^{2} \\ = \frac{1}{2} μ {C}_{ox} \frac{W}{L} {( EVDD + Vth - Vdata + Vref - EVDD - Vth )}^{2} \\ = \frac{1}{2} μ {C}_{o x} \frac{W}{L} {( - Vdata + Vref )}^{2}\end{matrix}$$

Here, Vgs is the gate-source voltage of the driving transistor DR.

$$μ {C}_{o x} \frac{W}{L}$$

is a constant value determined by the mobility (u), channel capacitance (Cox), channel width (W), and channel length (L) of the driving transistor DR. Vth is the threshold voltage of the driving transistor DR.

As can be seen from the above, the light-emitting elements MLD and RLD may be compensated by the threshold voltage Vth of the driving transistor DR during the emission phase so as not to be affected by a change in the threshold voltage Vth, and may be driven without being affected by RC delay or IR drop of the pixel driving voltage EVDD.

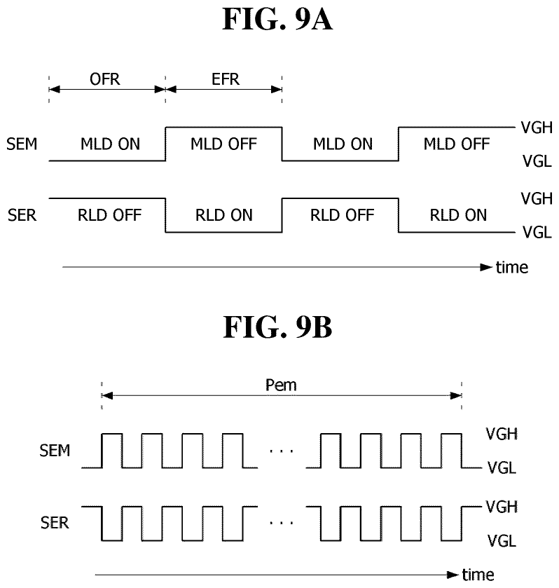

FIGS. 9A and 9B are diagrams illustrating a method of alternately driving the first and second light-emitting elements in the pixel circuits shown in FIGS. 4A to 7 according to an embodiment of the present disclosure. The first and second light-emitting elements may be alternately driven by the first and second selection signals SEM and SER.

Referring to FIGS. 9A and 9B, the voltages of the first and second selection signals SEM and SER may be generated as reverse phase waveforms so as to be opposite voltages to each other.

The voltages of the first and second selection signals SEM and SER may be alternately inverted in a periodicity of N (N is a natural number) frame periods, for example, 1 frame period, as illustrated in FIG. 9A. For example, during the first frame period OFR, the voltage of the first selection signal SEM may be the gate-on voltage, for example, the gate low voltage VGL, and the voltage of the second selection signal SER may be the gate-off voltage, for example, the gate high voltage VGH. Next, during the second frame period EFR, the voltage of the second selection signal SER may be the gate low voltage VGL, and the voltage of the first selection signal SEM may be the gate high voltage VGH. The first frame period OFR may be an odd-numbered frame period, and the second frame period EFR may be an even-numbered frame period. In this case, the first light-emitting element MLD may be driven to emit light during the first frame period OFR, while the second light-emitting element RLD may be driven to emit light during the second frame period EFR. Hence, even if one of the first and second light-emitting elements MLD and RLD of a specific sub-pixel cannot be driven due to a defect, the corresponding sub-pixel may be driven normally.

The voltages of the first and second selection signals SEM and SER may be alternately inverted one or more times during the fourth period Pem where the emission phase is performed within one frame period, as illustrated in FIG. 9B. For example, the voltage of the first selection signal SEM may be inverted multiple times within the fourth period Pem of a specific frame period, and the voltage of the second selection signal SER may be inverted in the opposite phase to the first selection signal SEM. In this case, the first light-emitting element MLD and the second light-emitting element RLD may be alternately driven to emit light within the fourth period Pem. Hence, even if one of the first and second light-emitting elements MLD and RLD of a specific sub-pixel cannot be driven due to a defect, the corresponding sub-pixel may be driven normally.

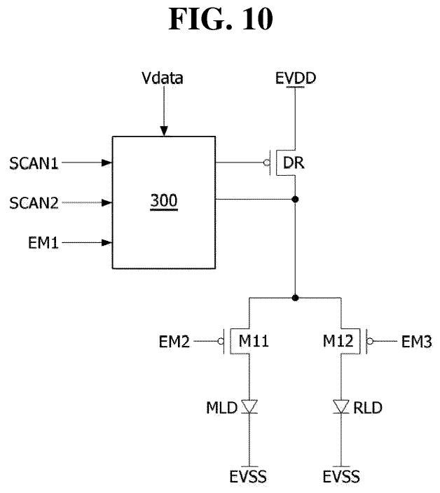

FIG. 10 is a circuit diagram showing a pixel circuit according to a third embodiment of the present disclosure. In this embodiment, descriptions overlapping with those of the above-described embodiments will be omitted.

Referring to FIG. 10, the pixel circuit may include a first light-emitting element MLD, a second light-emitting element RLD, a driving transistor DR, a plurality of switch transistors M11, M12, and a compensation circuit 300. The driving transistor DR and the switch transistors M11, M12 may be implemented with, but not limited to, p-channel transistors.

The first and second light-emitting elements MLD and RLD may be connected in parallel to the driving transistor DR through the switch transistors M11 and M12. The driving transistor DR may include a gate electrode to which the data voltage Vdata is applied, a first electrode to which the pixel driving voltage EVDD is applied, and a second electrode connected to the anode electrodes of the light-emitting elements MLD and RLD.

The first and second switch transistors M11 and M12 may be turned on/off according to the EM signals EM2 and EM3 output from the gate driver 120.

The first switch transistor M11 may be connected between the driving transistor DR and the anode electrode of the first light-emitting element MLD. The first switch transistor M11 may be turned on in response to the gate-on voltage of the second EM signal EM2, for example, the gate low voltage VGL, and may be turned off in response to the gate-off voltage of the second EM signal EM2, for example, the gate high voltage VGH. When the first switch transistor M11 is turned on, the first light-emitting element MLD may be electrically connected to the driving transistor DR, so that the first light-emitting element MLD may be driven.

The second switch transistor M12 may be connected between the driving transistor DR and the anode electrode of the second light-emitting element RLD. The second switch transistor M12 may be turned on in response to the gate-on voltage of the third EM signal EM3 and may be turned off in response to the gate-off voltage of the third EM signal EM3. When the second switch transistor M12 is turned on, the second light-emitting element RLD may be electrically connected to the driving transistor DR, so that the second light-emitting element RLD may be driven.

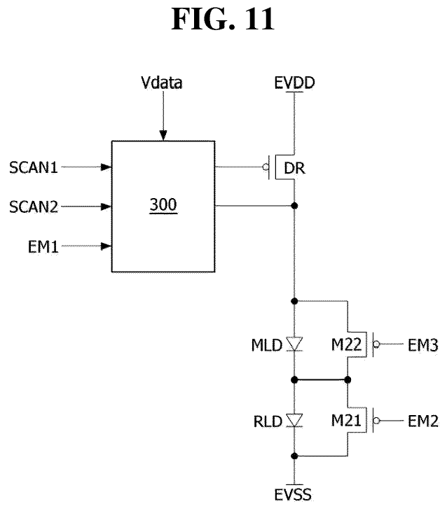

FIG. 11 is a circuit diagram showing a pixel circuit according to a fourth embodiment of the present disclosure. In this embodiment, descriptions overlapping with those of the above-described embodiments will be omitted.

Referring to FIG. 11, the driving transistor DR, the first light-emitting element MLD, and the second light-emitting element RLD may be connected in series between the pixel driving voltage EVDD and the ground voltage EVSS.

The first light-emitting element MLD may include an anode electrode connected to the second electrode of the driving transistor DR and a cathode electrode connected to the anode electrode of the second light-emitting element RLD. The second light-emitting element RLD may include an anode electrode connected to the cathode electrode of the first light-emitting element MLD and a cathode electrode to which the ground voltage EVSS is applied.

The first switch transistor M21 may be connected in parallel to both ends of the second light-emitting element RLD. The first switch transistor M21 may be turned on in response to the gate-on voltage of the second EM signal EM2 and may be turned off in response to the gate-off voltage of the second EM signal EM2. When the first switch transistor M21 is turned on, the both ends of the second light-emitting element RLD may be short-circuited. At this time, a current from the driving transistor DR flows to the first light-emitting element MLD so that the first light-emitting element MLD may be driven, while the second light-emitting element RLD may be in the off state with both ends short-circuited.

The second switch transistor M22 may be connected in parallel to both ends of the first light-emitting element MLD. The second switch transistor M22 may be turned on in response to the gate-on voltage of the third EM signal EM3 and may be turned off in response to the gate-off voltage of the third EM signal EM3. When the second switch transistor M22 is turned on, the both ends of the first light-emitting element MLD may be short-circuited. At this time, a current from the driving transistor DR flows to the second light-emitting element RLD so that the second light-emitting element RLD may be driven, while the first light-emitting element MLD may be in the off state with both ends short-circuited.

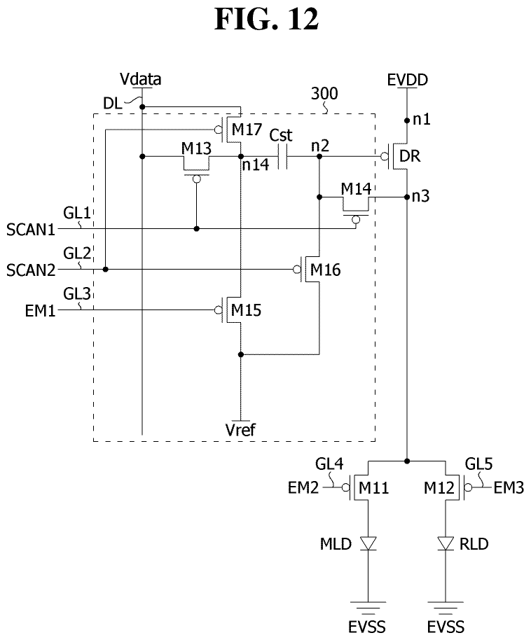

FIG. 12 is a circuit diagram showing in detail an example of the compensation circuit illustrated in FIG. 10 according to an embodiment of the present disclosure. In this embodiment, descriptions overlapping with those of the above-described embodiments will be omitted.

Referring to FIG. 12, the pixel driving voltage EVDD, ground voltage EVSS, and reference voltage Vref may be applied to the pixel circuit. The data voltage Vdata and gate signals SCAN1, SCAN2, EM1, EM2 and EM3 may be input to the pixel circuit.

The driving transistor DR may include a first electrode connected to the first node n1, a gate electrode connected to the second node n2, and a second electrode connected to the third node n3. The first node n1 may be connected to the power line to which the pixel driving voltage EVDD is applied.

The first switch transistor M11 may include a first electrode connected to the third node n3, a gate electrode connected to the fourth gate line GL4 to which the second EM signal EM2 is applied, and a second electrode connected to the anode electrode of the first light-emitting element MLD. The second switch transistor M12 may include a first electrode connected to the third node n3, a gate electrode connected to the fifth gate line GL5 to which the third EM signal EM3 is applied, and a second electrode connected to the anode electrode of the second light-emitting element RLD.

The first light-emitting element MLD may include an anode electrode connected to the second electrode of the first switch transistor M11, and a cathode electrode connected to the power line to which the ground voltage EVSS is applied. The second light-emitting element RLD may include an anode electrode connected to the second electrode of the second switch transistor M12, and a cathode electrode connected to the power line to which the ground voltage EVSS is applied.

The compensation circuit 300 may include a capacitor Cst and third to seventh switch transistors M13 to M17. The capacitor Cst may be connected between the second node n2 and the fourth node n14.

The third switch transistor M13 may be connected between the data line DL to which the data voltage Vdata is applied and the fourth node n14. The third switch transistor M13 may be turned on in response to the gate low voltage VGL of the first scan signal SCAN1 and may be turned off in response to the gate high voltage VGH of the first scan signal SCAN1. When the third switch transistor M13 is turned on, the data line DL may be electrically connected to the fourth node n14. The third switch transistor M13 may include a first electrode connected to the data line DL, a gate electrode connected to the first gate line GL1 to which the first scan signal SCAN1 is applied, and a second electrode connected to the fourth node n14.

The fourth switch transistor M14 may be connected between the second node n2 and the third node n3. The fourth switch transistor M14 may be turned on in response to the gate low voltage VGL of the first scan signal SCAN1 and may be turned off in response to the gate high voltage VGH of the first scan signal SCAN1. When the fourth switch transistor M14 is turned on, the second node n2 may be electrically connected to the third node n3. The fourth switch transistor M14 may include a first electrode connected to the second node n2, a gate electrode connected to the first gate line GL1, and a second electrode connected to the third node n3.

The fifth switch transistor M15 may be connected between the power line to which the reference voltage Vref is applied and the fourth node n14. The fifth switch transistor M15 may be turned on in response to the gate low voltage VGL of the first EM signal EM1 and may be turned off in response to the gate high voltage VGH of the first EM signal EM1. When the fifth switch transistor M15 is turned on, the reference voltage Vref may be applied to the fourth node n14. The fifth switch transistor M15 may include a first electrode connected to the fourth node n14, a gate electrode connected to the third gate line GL3 to which the first EM signal EM1 is applied, and a second electrode to which the reference voltage Vref is applied.

The sixth switch transistor M16 may be connected between the second node n2 and the power line to which the reference voltage Vref is applied. The sixth switch transistor M16 may be turned on in response to the gate low voltage VGL of the second scan signal SCAN2 and may be turned off in response to the gate high voltage VGH of the second scan signal SCAN2. When the sixth switch transistor M16 is turned on, the reference voltage Vref may be applied to the second node n2. The sixth switch transistor M16 may include a first electrode connected to the second node n2, a gate electrode connected to the second gate line GL2 to which the second scan signal SCAN2 is applied, and a second electrode to which the reference voltage Vref is applied.

The seventh switch transistor M17 may be connected between the data line DL to which the data voltage Vdata is applied and the fourth node n14. The seventh switch transistor M17 may be turned on in response to the gate low voltage VGL of the second scan signal SCAN2 and may be turned off in response to the gate high voltage VGH of the second scan signal SCAN2. When the seventh switch transistor M17 is turned on, the data line DL may be electrically connected to the fourth node n14. The seventh switch transistor M17 may include a first electrode connected to the data line DL, a gate electrode connected to the second gate line GL2, and a second electrode connected to the fourth node n14.

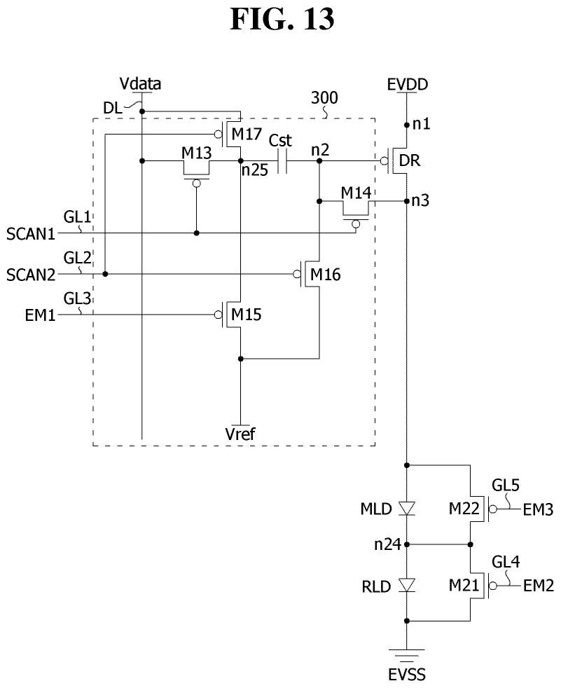

FIG. 13 is a circuit diagram showing in detail an example of the compensation circuit illustrated in FIG. 11 according to an embodiment of the present disclosure. In this embodiment, descriptions that are substantially the same as or overlapping with those of the above-described embodiments will be omitted.

Referring to FIG. 13, the driving transistor DR may include a first electrode connected to the first node n1, a gate electrode connected to the second node n2, and a second electrode connected to the third node n3.

The first light-emitting element MLD may include an anode electrode connected to the third node n3, and a cathode electrode connected to the fourth node n24. The second light-emitting element RLD may include an anode electrode connected to the fourth node n24, and a cathode electrode connected to the power line to which the ground voltage EVSS is applied.

The first switch transistor M21 may include a first electrode connected to the fourth node n24, a gate electrode connected to the fourth gate line GL4 to which the second EM signal EM2 is applied, and a second electrode connected to the cathode electrode of the second light-emitting element RLD. The second switch transistor M22 may include a first electrode connected to the third node n3, a gate electrode connected to the fifth gate line GL5 to which the third EM signal EM3 is applied, and a second electrode connected to the fourth node n24.

The capacitor Cst may be connected between the second node n2 and the fifth node n25. The third switch transistor M13 may be connected between the data line DL to which the data voltage Vdata is applied and the fifth node n25. When the third switch transistor M13 is turned on, the data line DL may be electrically connected to the fifth node n25. The third switch transistor M13 may include a first electrode connected to the data line DL, a gate electrode connected to the first gate line GL1 to which the first scan signal SCAN1 is applied, and a second electrode connected to the fifth node n25.

The fourth switch transistor M14 may be connected between the second node n2 and the third node n3. When the fourth switch transistor M14 is turned on, the second node n2 may be electrically connected to the third node n3.

The fifth switch transistor M15 may be connected between the power line to which the reference voltage Vref is applied and the fifth node n25. When the fifth switch transistor M15 is turned on, the reference voltage Vref may be applied to the fifth node n25. The fifth switch transistor M15 may include a first electrode connected to the fifth node n25, a gate electrode connected to the third gate line GL3 to which the first EM signal EM1 is applied, and a second electrode to which the reference voltage Vref is applied.

The sixth switch transistor M16 may be connected between the second node n2 and the power line to which the reference voltage Vref is applied. When the sixth switch transistor M16 is turned on, the reference voltage Vref may be applied to the second node n2.

The seventh switch transistor M17 may be connected between the data line DL and the fifth node n25. When the seventh switch transistor M17 is turned on, the data line DL may be electrically connected to the fifth node n25. The seventh switch transistor M17 may include a first electrode connected to the data line DL, a gate electrode connected to the second gate line GL2, and a second electrode connected to the fifth node n25.

The pixel circuits illustrated in FIGS. 10 to 13 may be driven in initialization, sampling, holding, and emission phases during one frame period.

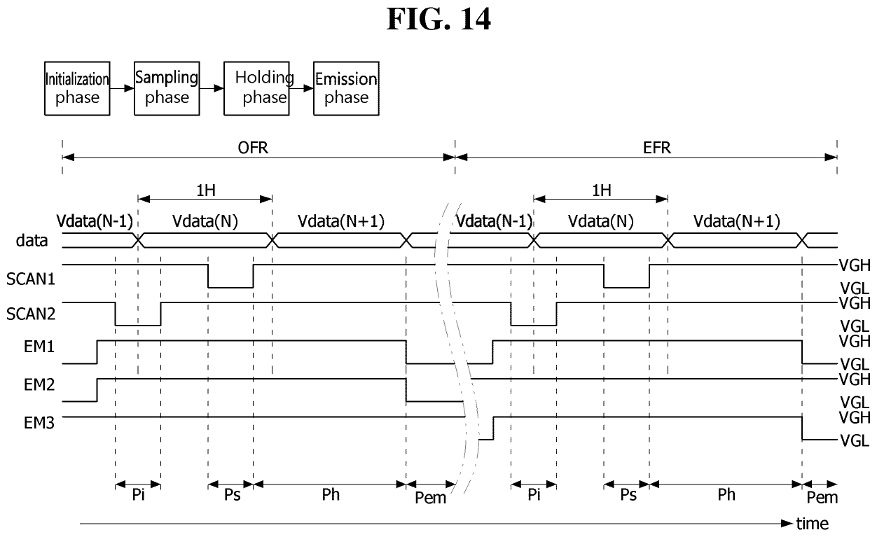

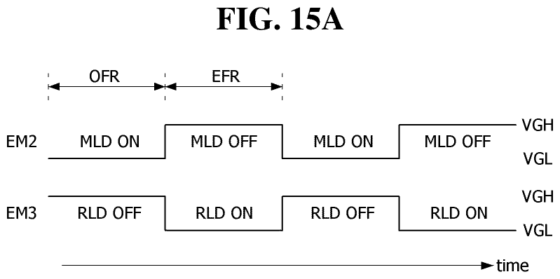

FIG. 14 is a waveform diagram illustrating input signals of the pixel circuits shown in FIGS. 10 to 13 according to an embodiment of the present disclosure. In FIG. 14, ‘OFR’ indicates the first frame period and ‘EFR’ indicates the second frame period.

Referring to FIGS. 12 to 14, the initialization phase may be performed during the first period Pi. During the first period Pi, the voltage of the second scan signal SCAN2 may be the gate low voltage VGL, and the voltages of the first scan signal SCAN1 and the EM signals EM1, EM2 and EM3 may be the gate high voltage VGH. Hence, during the first period Pi, the sixth and seventh switch transistors M16 and M17 may be turned on, while the first to fifth switch transistors M11 or M21, M12 or M22, M13 to M15 may be in the off state.

During the first period Pi, the reference voltage Vref may be applied to the second node n2, so that the gate voltage of the driving transistor DR may be initialized to the reference voltage Vref.

During the first period Pi, the data voltage Vdata(N−1) of the previous pixel line, for example, the n−1^{th} pixel line may be applied to the data line DL, and then the data voltage Vdata(N) of the current pixel line may be applied. The data voltage Vdata(N) may be applied through the seventh switch transistor M17 to the fourth node n14 illustrated in FIG. 12 and the fifth node n25 illustrated in FIG. 13.

The seventh switch transistor M17 may apply the same data voltage Vdata(N) as the data voltage Vdata(N) applied to the nodes n14 and n25 connected to one electrode of the capacitor Cst during the sampling phase to the nodes n14 and n25 during the initialization phase.

The sampling phase may be performed during the second period Ps. During the second period Ps, the voltage of the first scan signal SCAN1 may be the gate low voltage VGL, and the voltages of the second scan signal SCAN2 and the EM signals EM1, EM2 and EM3 may be the gate high voltage VGH. Hence, during the second period Ps, the third switch transistor M13 and the fourth switch transistor M14 may be turned on, whereas the first switch transistor M11 or M21, the second switch transistor M12 or M22, and the fifth to seventh switch transistors M15 to M17 may be in the off state.

In the second period Ps, the data voltage Vdata(N) compensated by the threshold voltage Vth of the driving transistor DR may be stored in the capacitor Cst.

The holding phase may be performed during the third period Ph. During the third period Ph, the voltages of the first scan signal SCAN1, the second scan signal SCAN2, and the first EM signal EM1 may be the gate high voltage VGH. Hence, during the third period Ph, the voltage of the capacitor Cst may remain at its previous state.

The emission phase may be performed during the fourth period Pem. During the fourth period Pem, the voltage of the first EM signal EM1 may be the gate low voltage VGL, and the voltages of the first scan signal SCAN1 and the second scan signal SCAN2 may be the gate high voltage VGH. Hence, during the fourth period Pem, the fifth switch transistor M15 may be turned on, while the third switch transistor M13, the fourth switch transistor M14, the sixth switch transistor M16, and the seventh switch transistor M17 may be in the off state. During the fourth period Pem, the driving transistor DR may generate a current according to the gate-source voltage, and the light-emitting elements MLD and RLD selected according to the second and third EM signals EM2 and EM3 may be alternately driven. When the second EM signal EM2 is at the gate low voltage VGL, the first light-emitting element MLD may be turned on and may be driven according to the current from the driving transistor DR to emit light. When the third EM signal EM3 is at the gate low voltage VGL, the second light-emitting element RLD may be turned on and may be driven according to the current from the driving transistor DR to emit light.

The light-emitting elements MLD and RLD may be compensated by the threshold voltage Vth of the driving transistor DR during the emission phase so as not to be affected by a change in the threshold voltage Vth and may be driven without being affected by RC delay or IR drop of the pixel driving voltage EVDD.

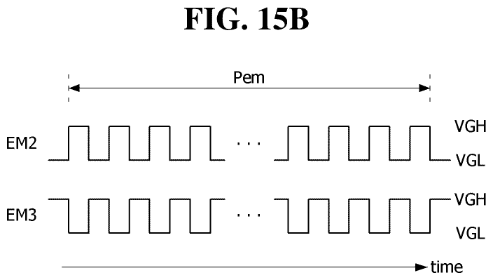

FIGS. 15A and 15B are diagrams illustrating a method of alternately driving the first and second light-emitting elements in the pixel circuits shown in FIGS. 10 to 13 according to an embodiment of the present disclosure. The first and second light-emitting elements MLD and RLD may be alternately driven according to the second and third EM signals EM2 and EM3.

Referring to FIGS. 15A and 15B, the voltages of the second and third EM signals EM2 and EM3 may be generated as reverse phase waveforms so as to be opposite voltages to each other.

The voltages of the second and third EM signals EM2 and EM3 may be alternately inverted in a periodicity of N frame periods, for example, 1 frame period, as illustrated in FIG. 15A. For example, during the first frame period OFR, the voltage of the second EM signal EM2 may be the gate-on voltage, for example, the gate low voltage VGL, and the voltage of the third EM signal EM3 may be the gate-off voltage, for example, the gate high voltage VGH. Next, during the second frame period EFR, the voltage of the third EM signal EM3 may be the gate low voltage VGL, and the voltage of the second EM signal EM2 may be the gate high voltage VGH. In this case, the first light-emitting element MLD may be driven to emit light during the first frame period OFR, while the second light-emitting element RLD may be driven to emit light during the second frame period EFR. Hence, even if one of the first and second light-emitting elements MLD and RLD of a specific sub-pixel cannot be driven due to a defect, the corresponding sub-pixel may be driven normally.

The voltages of the second and third EM signals EM2 and EM3 may be alternately inverted one or more times during the fourth period Pem as illustrated in FIG. 15B. For example, the voltage of the second EM signal EM2 may be inverted multiple times within the fourth period Pem of a specific frame period, and the voltage of the third EM signal EM3 may be inverted in the opposite phase to the second EM signal EM2. In this case, the first light-emitting element MLD and the second light-emitting element RLD may be alternately driven to emit light within the fourth period Pem. Hence, even if one of the first and second light-emitting elements MLD and RLD of a specific sub-pixel cannot be driven due to a defect, the corresponding sub-pixel may be driven normally.

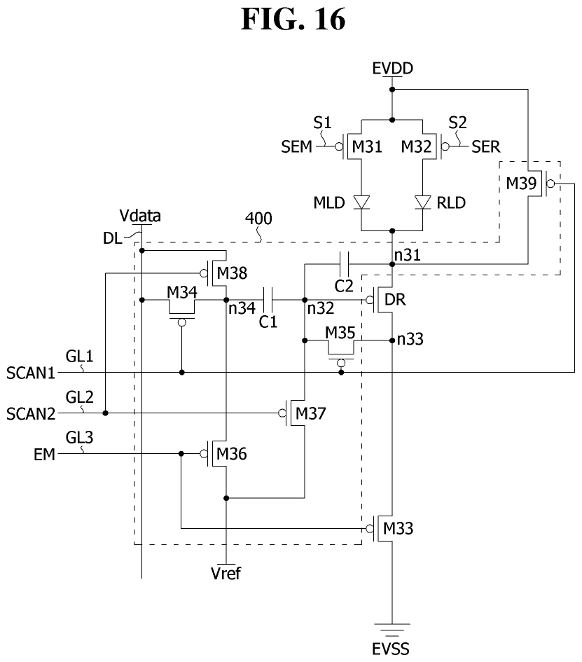

FIG. 16 is a circuit diagram showing a pixel circuit according to a fifth embodiment of the present disclosure.

Referring to FIG. 16, the pixel circuit may include a first light-emitting element MLD, a second light-emitting element RLD, a driving transistor DR, a first switch transistor M31, a second switch transistor M32, a third switch transistor M33, and a compensation circuit 400. The driving transistor DR, the first to third switch transistors M31, M32 and M33, and the transistors M34 to M38 of the compensation circuit 400 may be implemented with, but not limited to, p-channel transistors.

The first and second light-emitting elements MLD and RLD may be connected in parallel to the driving transistor DR and may be connected in parallel to the power line to which the pixel driving voltage EVDD is applied through the first and second switch transistors M31 and M32.

The driving transistor DR may include a first electrode connected to the first node n31, a gate electrode connected to the second node n32, and a second electrode connected to the third node n33. The first light-emitting element MLD may include an anode electrode connected to the second electrode of the first switch transistor M31, and a cathode electrode connected to the first node n31. The second light-emitting element RLD may include an anode electrode connected to the second electrode of the second switch transistor M32, and a cathode electrode connected to the first node n31.

The first and second switch transistors M31 and M32 may be turned on/off according to the selection signals SEM and SER illustrated in FIGS. 8, 9A and 9B. In addition, the first and second switch transistors M31 and M32 may be turned on/off according to the EM signals EM1 and EM2 illustrated in FIGS. 14, 15A and 15B. The selection signals SEM and SER may be output from the selector 140. The EM signals EM1 and EM2 may be output from the gate driver 120. In FIG. 16, the EM signals EM2 and EM3 are omitted. The third switch transistor M33 may be turned on/off according to the EM signal EM output from the gate driver 120.

The first switch transistor M31 may be connected between the power line to which the pixel driving voltage EVDD is applied and the first light-emitting element MLD. The first switch transistor M31 may be turned on in response to the gate-on voltage, for example, the gate low voltage VGL of the first selection signal SEM or the second EM signal EM2, and may be turned off in response to the gate-off voltage, for example, the gate high voltage VGH of the first selection signal SEM or the second EM signal EM2. When the first switch transistor M31 is turned on, the pixel driving voltage EVDD may be applied to the anode electrode of the first light-emitting element MLD. The first switch transistor M31 may include a first electrode to which the pixel driving voltage EVDD is applied, a gate electrode to which the first selection signal SEM or second EM signal EM2 is applied, and a second electrode connected to the anode electrode of the first light-emitting element MLD.

The second switch transistor M32 may be connected between the power line to which the pixel driving voltage EVDD is applied and the second light-emitting element RLD. The second switch transistor M32 may be turned on in response to the gate low voltage VGL of the second selection signal SER or third EM signal EM3 and may be turned off in response to the gate high voltage VGH of the second selection signal SER or third EM signal EM3. When the second switch transistor M32 is turned on, the pixel driving voltage EVDD may be applied to the anode electrode of the second light-emitting element RLD. The second switch transistor M32 may include a first electrode to which the pixel driving voltage EVDD is applied, a gate electrode to which the second selection signal SER or third EM signal EM3 is applied, and a second electrode connected to the anode electrode of the second light-emitting element RLD.

The third switch transistor M33 may be connected between the driving transistor DR and the power line to which the ground voltage EVSS is applied. The third switch transistor M33 may be turned on in response to the gate low voltage VGL of the EM signal EM and may be turned off in response to the gate high voltage VGH of the EM signal EM. When the third switch transistor M33 is turned on, the second electrode of the driving transistor DR may be connected to the power line to which the ground voltage EVDD is applied. The third switch transistor M33 may include a first electrode connected to the third node n33, a gate electrode to which the EM signal EM is applied, and a second electrode to which the ground voltage EVSS is applied.

The compensation circuit 400 may be connected to the data line to which the data voltage Vdata is applied and the gate lines to which the gate signals SCAN1, SCAN2 and EM are applied. The compensation circuit 400 may include fourth to ninth switch transistors M34 to M39 and capacitors C1 and C2. The compensation circuit 400 may sample the threshold voltage of the driving transistor DR in the capacitors C1 and C2 to compensate the gate voltage of the driving transistor DR by the threshold voltage of the driving transistor DR.

The first capacitor C1 may be connected between the second node n32 and the fourth node n34. The second capacitor C2 may be connected between the first node n31 and the second node n32.

The fourth switch transistor M34 may be connected between the data line DL to which the data voltage Vdata is applied and the fourth node n34. The fourth switch transistor M34 may be turned on in response to the gate low voltage VGL of the first scan signal SCAN1 and may be turned off in response to the gate high voltage VGH of the first scan signal SCAN1. When the fourth switch transistor M34 is turned on, the data line DL may be electrically connected to the fourth node n34. The fourth switch transistor M34 may include a first electrode connected to the data line DL, a gate electrode to which the first scan signal SCAN1 is applied, and a second electrode connected to the fourth node n34.

The fifth switch transistor M35 may be connected between the second node n32 and the third node n33. The fifth switch transistor M35 may be turned on in response to the gate low voltage VGL of the first scan signal SCAN1 and may be turned off in response to the gate high voltage VGH of the first scan signal SCAN1. When the fifth switch transistor M35 is turned on, the second node n32 may be electrically connected to the third node n33. The fifth switch transistor M35 may include a first electrode connected to the second node n32, a gate electrode to which the first scan signal SCAN1 is applied, and a second electrode connected to the third node n33.

The sixth switch transistor M36 may be connected between the power line to which the reference voltage Vref is applied and the fourth node n34. The sixth switch transistor M36 may be turned on in response to the gate low voltage VGL of the EM signal EM and may be turned off in response to the gate high voltage VGH of the EM signal EM. When the sixth switch transistor M36 is turned on, the reference voltage Vref may be applied to the fourth node n34. The sixth switch transistor M36 may include a first electrode connected to the fourth node n34, a gate electrode to which the EM signal EM is applied, and a second electrode to which the reference voltage Vref is applied.

The seventh switch transistor M37 may be connected between the second node n32 and the power line to which the reference voltage Vref is applied. The seventh switch transistor M37 may be turned on in response to the gate low voltage VGL of the second scan signal SCAN2 and may be turned off in response to the gate high voltage VGH of the second scan signal SCAN2. When the seventh switch transistor M37 is turned on, the reference voltage Vref may be applied to the second node n32. The seventh switch transistor M37 may include a first electrode connected to the second node n32, a gate electrode to which the second scan signal SCAN2 is applied, and a second electrode to which the reference voltage Vref is applied.

The eighth switch transistor M38 may be connected between the data line DL to which the data voltage Vdata is applied and the fourth node n34. The eighth switch transistor M38 may be turned on in response to the gate low voltage VGL of the second scan signal SCAN2 and may be turned off in response to the gate high voltage VGH of the second scan signal SCAN2. When the eighth switch transistor M38 is turned on, the data line DL may be electrically connected to the fourth node n34. The eighth switch transistor M38 may include a first electrode connected to the data line DL, a gate electrode to which the second scan signal SCAN2 is applied, and a second electrode connected to the fourth node n34.

The ninth switch transistor M39 may be connected between the power line to which the pixel driving voltage EVDD is applied and the first node n31. The ninth switch transistor M39 may be turned on in response to the gate low voltage VGL of the first scan signal SCAN1 and may be turned off in response to the gate high voltage VGH of the first scan signal SCAN1. When the ninth switch transistor M39 is turned on, the power line to which the pixel driving voltage EVDD is applied is electrically connected to the first node n31, so that the first and second light-emitting elements MLD and RLD are not driven. The ninth switch transistor M39 may include a first electrode connected to the power line to which the pixel driving voltage EVDD is applied, a gate electrode to which the first scan signal SCAN1 is applied, and a second electrode connected to the first node n31.

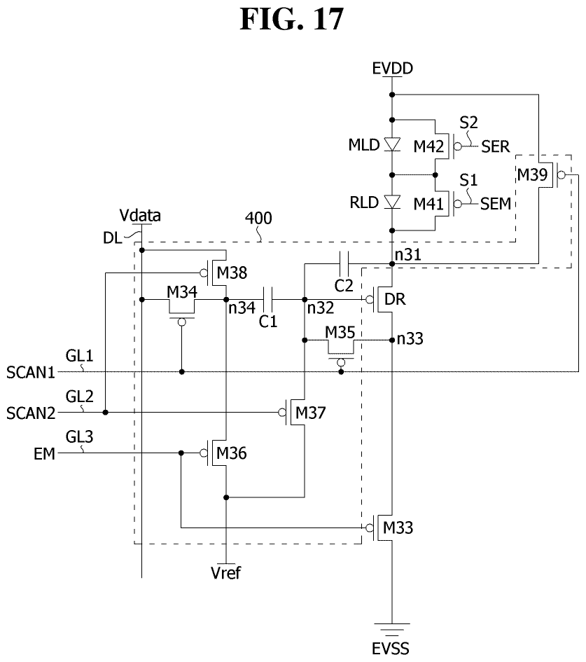

FIG. 17 is a circuit diagram showing a pixel circuit according to a sixth embodiment of the present disclosure. In this embodiment, descriptions that are substantially the same as or overlapping with those of the above-described embodiment illustrated in FIG. 16 may be omitted. For example, descriptions of the third switch transistor M33 and the compensation circuit 400 are omitted.

Referring to FIG. 17, the first and second light-emitting elements MLD and RLD may be connected in series between the power line to which the pixel driving voltage EVDD is applied and the first node n31. The first light-emitting element MLD may include an anode electrode connected to the power line to which the pixel driving voltage EVDD is applied, and a cathode electrode connected to the anode electrode of the second light-emitting element RLD. The second light-emitting element RLD may include an anode electrode connected to the cathode electrode of the first light-emitting element MLD, and a cathode electrode connected to the first node n31.

The first and second switch transistors M41 and M42 may be turned on/off according to the selection signals SEM and SER illustrated in FIGS. 9A and 9B. Additionally, the first and second switch transistors M41 and M42 may be turned on/off according to the EM signals EM2 and EM3 illustrated in FIGS. 15A and 15B.

The first switch transistor M41 may include a first electrode connected to the anode electrode of the second light-emitting element RLD, a gate electrode to which the first selection signal SEM or second EM signal EM2 is applied, and a second electrode connected to the cathode electrode of the second light-emitting element RLD. The second switch transistor M42 may include a first electrode connected to the anode electrode of the first light-emitting element MLD, a gate electrode to which the second selection signal SER or third EM signal EM3 is applied, and a second electrode connected to the cathode electrode of the first light-emitting element MLD.

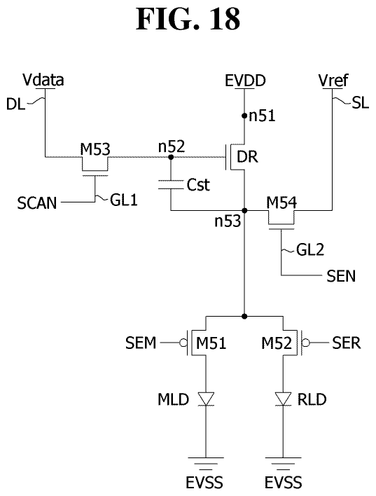

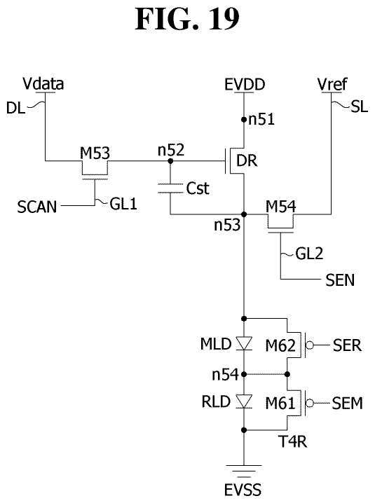

The pixel circuit may be connected to an external compensation circuit via the sensing line SL illustrated in FIGS. 18 and 19.

FIG. 18 is a circuit diagram showing a pixel circuit according to a seventh embodiment of the present disclosure.

Referring to FIG. 18, the pixel circuit may include a first light-emitting element MLD, a second light-emitting element RLD, a driving transistor DR, a capacitor Cst, and a plurality of switch transistors M51 to M54. The first and second switch transistors M51 and M52 may be implemented with, but not limited to, p-channel transistors. The driving transistor DR, the third switch transistor M53, and the fourth switch transistor M54 may be implemented with, but not limited to, n-channel transistors.

The first and second light-emitting elements MLD and RLD may be connected in parallel to the driving transistor DR through the first and second switch transistors M51 and M52.

The driving transistor DR may include a first electrode connected to the first node n51, a gate electrode connected to the second node n52, and a second electrode connected to the third node n53. The pixel driving voltage EVDD may be applied to the first node n51. The capacitor Cst may be connected between the second node n52 and the third node n53.

The first light-emitting element MLD may include an anode electrode connected to the second electrode of the first switch transistor M51 and a cathode electrode to which the ground voltage EVSS is applied. The second light-emitting element RLD may include an anode electrode connected to the second electrode of the second switch transistor M52, and a cathode electrode to which the ground voltage EVSS is applied.

The first and second switch transistors M51 and M52 may be turned on/off according to the selection signals SEM and SER illustrated in FIGS. 9A and 9B. Additionally, the first and second switch transistors M51 and M52 may be turned on/off according to the EM signals EM2 and EM3 illustrated in FIGS. 15A and 15B.

The first switch transistor M51 may be turned on in response to the gate-on voltage, for example, the gate low voltage VGL of the first selection signal SEM or second EM signal EM2 and may be turned off in response to the gate-off voltage, for example, the gate high voltage VGH of the first selection signal SEM or second EM signal EM2. When the first switch transistor M51 is turned on, the second electrode of the driving transistor DR may be connected to the anode electrode of the first light-emitting element MLD. The first switch transistor M51 may include a first electrode connected to the third node n53, a gate electrode to which the first selection signal SEM or second EM signal EM2 is applied, and a second electrode connected to the anode electrode of the first light-emitting element MLD.

The second switch transistor M52 may be turned on in response to the gate-on voltage, for example, the gate low voltage VGL of the second selection signal SER or third EM signal EM3 and may be turned off in response to the gate-off voltage, for example, the gate high voltage VGH of the second selection signal SER or third EM signal EM3. When the second switch transistor M52 is turned on, the second electrode of the driving transistor DR may be connected to the anode electrode of the second light-emitting element RLD. The second switch transistor M52 may include a first electrode connected to the third node n53, a gate electrode to which the second selection signal SER or third EM signal EM3 is applied, and a second electrode connected to the anode electrode of the second light-emitting element RLD.

The third switch transistor M53 may be connected between the data line DL to which the data voltage Vdata is applied and the second node n52. The third switch transistor M53 may be turned on in response to the gate-on voltage, for example, the gate high voltage VGH of the first scan signal SCAN and may be turned off in response to the gate-off voltage, for example, the gate low voltage VGL of the first scan signal SCAN. When the third switch transistor M53 is turned on, the data line DL may be electrically connected to the second node n52. The third switch transistor M53 may include a first electrode connected to the data line DL, a gate electrode connected to the first gate line GL1 to which the first scan signal SCAN is applied, and a second electrode connected to the second node n52.

The fourth switch transistor M54 may be connected between the third node n53 and the sensing line SL. An external compensation circuit may be connected to the sensing line SL. The sensing line SL may be initialized when the reference voltage Vref is applied. The fourth switch transistor M54 may be turned on in response to the gate-on voltage, for example, the gate high voltage VGH of the second scan signal SEN, and may be turned off in response to the gate-off voltage, for example, the gate low voltage VGL of the second scan signal SEN. The pulse of the second scan signal SEN may be generated in phase with the pulse of the first scan signal SCAN. When the fourth switch transistor M54 is turned on, the sensing line SL may be electrically connected to the third node n53. The fourth switch transistor M54 may include a first electrode connected to the third node n53, a gate electrode connected to the second gate line GL2 to which the second scan signal SEN is applied, and a second electrode connected to the sensing line SL.

FIG. 19 is a circuit diagram showing a pixel circuit according to an eighth embodiment of the present disclosure. In this embodiment, descriptions that are substantially the same as or overlapping with those of the above-described embodiment illustrated in FIG. 18 will be omitted. For example, descriptions of the driving transistor DR, the third switch transistor M53, and the fourth switch transistor M54 are omitted.

Referring to FIG. 19, the first and second light-emitting elements MLD and RLD may be connected in series between the third node n53 and the power line to which the ground voltage EVSS is applied. The first light-emitting element MLD may include an anode electrode connected to the third node n53, and a cathode electrode connected to the fourth node n54. The second light-emitting element RLD may include an anode electrode connected to the fourth node n54, and a cathode electrode connected to the power line to which the ground voltage EVSS is applied.

The first and second switch transistors M61 and M62 may be turned on/off according to the selection signals SEM and SER illustrated in FIGS. 9A and 9B. Additionally, the first and second switch transistors M61 and M62 may be turned on/off according to the EM signals EM2 and EM3 illustrated in FIGS. 15A and 15B.

The first switch transistor M61 may include a first electrode connected to the anode electrode of the second light-emitting element RLD, a gate electrode to which the first selection signal SEM or second EM signal EM2 is applied, and a second electrode connected to the cathode electrode of the second light-emitting element RLD. The second switch transistor M62 may include a first electrode connected to the anode electrode of the first light-emitting element MLD, a gate electrode to which the second selection signal SER or third EM signal EM3 is applied, and a second electrode connected to the cathode electrode of the first light-emitting element MLD. One or more embodiments of the present disclosure may be described as follows.

According to one or more embodiments of the present disclosure, a pixel circuit may include a driving transistor configured to generate a current; and first and second light-emitting elements electrically connected in parallel or in series to the driving transistor. The first and second light-emitting elements may be alternately driven by the current from the driving transistor.

According to one or more embodiments of the present disclosure, the pixel circuit may further include: a first switch transistor; a second switch transistor; and a third switch transistor. The first and second light-emitting elements may be connected in parallel to the driving transistor through the first switch transistor, the second switch transistor, and the third switch transistor.

According to one or more embodiments of the present disclosure, the first switch transistor may be connected between the third switch transistor and an anode electrode of the first light-emitting element and may be turned on in response to a first control signal applied to a gate electrode of the first switch transistor. The second switch transistor may be connected between the third switch transistor and an anode electrode of the second light-emitting element and may be turned on in response to a second control signal applied to a gate electrode of the second switch transistor. The third switch transistor may electrically connect the driving transistor to the first or second switch transistor when turned on in response to a third control signal applied to a gate electrode of the third switch transistor.

According to one or more embodiments of the present disclosure, the pixel circuit may further include: a first switch transistor; a second switch transistor; and a third switch transistor. The first and second light-emitting elements may be connected in series to the driving transistor through the third switch transistor. The first switch transistor may be connected between both ends of the second light-emitting element and may be turned on in response to a first control signal applied to a gate electrode of the first switch transistor. The second switch transistor may be connected between both ends of the first light-emitting element and may be turned on in response to a second control signal applied to a gate electrode of the second switch transistor. The third switch transistor may electrically connect the driving transistor to an anode electrode of the first light-emitting element when turned on in response to a third control signal applied to a gate electrode of the third switch transistor.

According to one or more embodiments of the present disclosure, the driving transistor may include first electrode connected to a first node, a gate electrode connected to a second node, and a second electrode connected to a third node.

According to one or more embodiments of the present disclosure, the pixel circuit may further include: a first switch transistor including a first electrode connected to a fourth node, a gate electrode to which a first control signal is applied, and a second electrode connected to an anode electrode of the first light-emitting element; a second switch transistor including a first electrode connected to the fourth node, a gate electrode to which a second control signal is applied, and a second electrode connected to an anode electrode of the second light-emitting element; a third switch transistor including a first electrode connected to the third node, a gate electrode to which an emission signal is applied, and a second electrode connected to the fourth node; a fourth switch transistor including a first electrode connected to a data line to which a data voltage is applied, a gate electrode to which a first scan signal is applied, and a second electrode connected to a fifth node; a fifth switch transistor including a first electrode connected to the second node, a gate electrode to which the first scan signal is applied, and a second electrode connected to the third node; a sixth switch transistor including a first electrode connected to the fifth node, a gate electrode to which the emission signal is applied, and a second electrode to which a reference voltage is applied; a seventh switch transistor including a first electrode connected to the second node, a gate electrode to which a second scan signal is applied, and a second electrode to which the reference voltage is applied; an eighth switch transistor including a first electrode connected to the data line, a gate electrode to which the second scan signal is applied, and a second electrode connected to the fifth node; and a capacitor connected between the second node and the fifth node. The first light-emitting element may include an anode electrode connected to the second electrode of the first switch transistor, and a cathode electrode to which a ground voltage is applied. The second light-emitting element may include an anode electrode connected to the second electrode of the second switch transistor, and a cathode electrode to which the ground voltage is applied.

According to one or more embodiments of the present disclosure, the pixel circuit may further include: a first switch transistor including a first electrode connected to a fifth node, a gate electrode to which a first control signal is applied, and a second electrode connected to a cathode electrode of the second light-emitting element; a second switch transistor including a first electrode connected to a fourth node, a gate electrode to which a second control signal is applied, and a second electrode connected to the fifth node; a third switch transistor including a first electrode connected to the third node, a gate electrode to which an emission signal is applied, and a second electrode connected to the fourth node; a fourth switch transistor including a first electrode connected to a data line to which a data voltage is applied, a gate electrode to which a first scan signal is applied, and a second electrode connected to a sixth node; a fifth switch transistor including a first electrode connected to the second node, a gate electrode to which the first scan signal is applied, and a second electrode connected to the third node; a sixth switch transistor including a first electrode connected to the sixth node, a gate electrode to which the emission signal is applied, and a second electrode to which a reference voltage is applied; a seventh switch transistor including a first electrode connected to the second node, a gate electrode to which a second scan signal is applied, and a second electrode to which the reference voltage is applied; an eighth switch transistor including a first electrode connected to the data line, a gate electrode to which the second scan signal is applied, and a second electrode connected to the sixth node; and a capacitor connected between the second node and the sixth node. The first light-emitting element may include an anode electrode connected to the fourth node, and a cathode electrode connected to the fifth node. The second light-emitting element may include an anode electrode connected to the fifth node, and a cathode electrode to which a ground voltage is applied.

According to one or more embodiments of the present disclosure, the pixel circuit may further include: a first switch transistor including a first electrode connected to the third node, a gate electrode to which a first control signal is applied, and a second electrode connected to an anode electrode of the first light-emitting element; and a second switch transistor including a first electrode connected to the third node, a gate electrode to which a second control signal is applied, and a second electrode connected to an anode electrode of the second light-emitting element. The first light-emitting element may include an anode electrode connected to the second electrode of the first switch transistor, and a cathode electrode to which a ground voltage is applied. The second light-emitting element may include an anode electrode connected to the second electrode of the second switch transistor, and a cathode electrode to which the ground voltage is applied.

According to one or more embodiments of the present disclosure, the pixel circuit may further include: a first switch transistor including a first electrode connected to a fourth node, a gate electrode to which a first control signal is applied, and a second electrode connected to a cathode electrode of the second light-emitting element; and a second switch transistor including a first electrode connected to the third node, a gate electrode to which a second control signal is applied, and a second electrode connected to the fourth node. The first light-emitting element may include an anode electrode connected to the third node, and a cathode electrode connected to the fourth node. The second light-emitting element may include an anode electrode connected to the fourth node, and a cathode electrode to which a ground voltage is applied.

According to one or more embodiments of the present disclosure, the pixel circuit may further include: a first switch transistor including a first electrode to which a pixel driving voltage is applied, a gate electrode to which a first control signal is applied, and a second electrode connected to an anode electrode of the first light-emitting element; and a second switch transistor including a first electrode to which the pixel driving voltage is applied, a gate electrode to which a second control signal is applied, and a second electrode connected to an anode electrode of the second light-emitting element. The first light-emitting element may include an anode electrode connected to the second electrode of the first switch transistor, and a cathode electrode connected to the first node. The second light-emitting element may include an anode electrode connected to the second electrode of the second switch transistor, and a cathode electrode connected to the first node.

According to one or more embodiments of the present disclosure, the pixel circuit may further include: a first switch transistor including a first electrode connected to an anode electrode of the second light-emitting element, a gate electrode to which a first control signal is applied, and a second electrode connected to a cathode electrode of the second light-emitting element; and a second switch transistor including a first electrode connected to an anode electrode of the first light-emitting element, a gate electrode to which a second control signal is applied, and a second electrode connected to a cathode electrode of the first light-emitting element. The first light-emitting element and the second light-emitting element are connected in series between a power line to which a pixel driving voltage is applied and the first node.

According to one or more embodiments of the present disclosure, the pixel circuit may further include: a first capacitor connected between the second node and a fourth node; a second capacitor connected between the first node and the second node; a third switch transistor including a first electrode connected to the third node, a gate electrode to which an emission signal is applied, and a second electrode to which a ground voltage is applied; a fourth switch transistor including a first electrode connected to a data line to which a data voltage is applied, a gate electrode to which a first scan signal is applied, and a second electrode connected to the fourth node; a fifth switch transistor including a first electrode connected to the second node, a gate electrode to which the first scan signal is applied, and a second electrode connected to the third node; a sixth switch transistor including a first electrode connected to the fourth node, a gate electrode to which the emission signal is applied, and a second electrode to which a reference voltage is applied; a seventh switch transistor including a first electrode connected to the second node, a gate electrode to which a second scan signal is applied, and a second electrode to which the reference voltage is applied; an eighth switch transistor including a first electrode connected to the data line, a gate electrode to which the second scan signal is applied, and a second electrode connected to the fourth node; and a ninth switch transistor including a first electrode to which a pixel driving voltage is applied, a gate electrode to which the first scan signal is applied, and a second electrode connected to the first node.

According to one or more embodiments of the present disclosure, one frame period may include a first period, a second period set after the first period, a third period set after the second period, and a fourth period set after the third period. During the first period, a voltage of the second scan signal may be a gate-on voltage, and voltages of the first scan signal and the emission signal may be a gate-off voltage. During the second period, the voltage of the first scan signal may be the gate-on voltage, and the voltages of the second scan signal and the emission signal may be the gate-off voltage. During the third period, the voltages of the first scan signal, the second scan signal, and the emission signal may be the gate-off voltage. During the fourth period, the voltage of the emission signal may be the gate-on voltage, and the voltages of the first scan signal and the second scan signal may be the gate-off voltage. Each of the switch transistors may be turned on in response to the gate-on voltage and is turned off in response to the gate-off voltage.

According to one or more embodiments of the present disclosure, the pixel circuit may further include: a first switch transistor including a first electrode connected to the third node, a gate electrode to which a first control signal is applied, and a second electrode connected to an anode electrode of the first light-emitting element; a second switch transistor including a first electrode connected to the third node, a gate electrode to which a second control signal is applied, and a second electrode connected to an anode electrode of the second light-emitting element; a third switch transistor including a first electrode connected to a data line to which a data voltage is applied, a gate electrode to which a first scan signal is applied, and a second electrode connected to the second node; and a fourth switch transistor including a first electrode connected to the third node, a gate electrode to which a second scan signal is applied, and a second electrode connected to a sensing line. The first light-emitting element may include an anode electrode connected to the second electrode of the first switch transistor, and a cathode electrode to which a ground voltage is applied. The second light-emitting element may include an anode electrode connected to the second electrode of the second switch transistor, and a cathode electrode to which the ground voltage is applied.

According to one or more embodiments of the present disclosure, the pixel circuit may further include: a first switch transistor including a first electrode connected to an anode electrode of the second light-emitting element, a gate electrode to which a first control signal is applied, and a second electrode connected to a cathode electrode of the second light-emitting element; a second switch transistor including a first electrode connected to an anode electrode of the first light-emitting element, a gate electrode to which a second control signal is applied, and a second electrode connected to a cathode electrode of the first light-emitting element; a third switch transistor including a first electrode connected to a data line to which a data voltage is applied, a gate electrode to which a first scan signal is applied, and a second electrode connected to the second node; and a fourth switch transistor including a first electrode connected to the third node, a gate electrode to which a second scan signal is applied, and a second electrode connected to a sensing line. The first light-emitting element may include an anode electrode connected to the third node, and a cathode electrode connected to a fourth node. The second light-emitting element may include an anode electrode connected to the fourth node, and a cathode electrode connected to a power line to which a ground voltage is applied.

According to one or more embodiments of the present disclosure, the voltages of the first and second control signals may be alternately inverted in a periodicity of N (N is a natural number) frame periods or alternately inverted during an emission period within one frame period.

According to one or more embodiments of the present disclosure, the voltages of the first and second control signals may be alternately inverted in a periodicity of one frame period.

According to one or more embodiments of the present disclosure, a display device may include: a display panel on which a plurality of data lines, a plurality of gate lines, and a plurality of pixel circuits are arranged; a data driving circuit connected to the data lines; and a gate driving circuit connected to the gate lines. Each of the pixel circuits may include: a driving transistor configured to generate a current; and first and second light-emitting elements electrically connected in parallel or in series to the driving transistor. The first and second light-emitting elements may be alternately driven by the current from the driving transistor.

According to one or more embodiments of the present disclosure, the display device may be applied to mobile apparatuses, video phones, smart watches, watch phones, wearable apparatus, foldable apparatus, rollable apparatus, bendable apparatus, flexible apparatus, curved apparatus, sliding apparatus, variable apparatus, electronic organizer, electronic books, portable multimedia players (PMPs), personal digital assistants (PDAs), MP3 players, mobile medical apparatuses, desktop PCs, laptop PCs, netbook computers, workstations, navigations, vehicle navigations, vehicle display apparatuses, vehicle apparatuses, theater apparatuses, theater display apparatuses, televisions, wallpaper apparatuses, signage apparatuses, game apparatuses, laptops, monitors, cameras, camcorders, and home appliances, etc. Additionally, the display device according to one or more embodiments of the present disclosure may be applied to organic light emitting lighting apparatuses or inorganic light emitting lighting apparatuses.

The objects to be achieved by the present disclosure, the means for achieving the objects, and effects of the present disclosure described above do not specify essential features of the claims, and thus, the scope of the claims is not limited to the detailed description of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A pixel circuit comprising:
a driving transistor configured to generate a current; and
a first light-emitting element and a second light-emitting element electrically connected in parallel or in series to the driving transistor,
wherein the first light-emitting element and the second light-emitting element are alternately driven by the current from the driving transistor.

2. The pixel circuit of claim 1, further comprising:
a first switch transistor;
a second switch transistor; and
a third switch transistor,
wherein the first light-emitting element and the second light-emitting element are connected in parallel to the driving transistor through the first switch transistor, the second switch transistor, and the third switch transistor,
wherein the first switch transistor is connected to the third switch transistor and an anode electrode of the first light-emitting element, and is turned on in response to a first control signal applied to a gate electrode of the first switch transistor,
wherein the second switch transistor is connected to the third switch transistor and an anode electrode of the second light-emitting element, and is turned on in response to a second control signal applied to a gate electrode of the second switch transistor, and
wherein the third switch transistor electrically connects the driving transistor to the first switch transistor or the second switch transistor when turned on in response to a third control signal applied to a gate electrode of the third switch transistor.

3. The pixel circuit of claim 1, further comprising:
a first switch transistor;
a second switch transistor; and
a third switch transistor,
wherein the first light-emitting element and the second light-emitting element are connected in series to the driving transistor through the third switch transistor,
wherein the first switch transistor is connected to both ends of the second light-emitting element, and is turned on in response to a first control signal applied to a gate electrode of the first switch transistor,
wherein the second switch transistor is connected to both ends of the first light-emitting element, and is turned on in response to a second control signal applied to a gate electrode of the second switch transistor, and
wherein the third switch transistor electrically connects the driving transistor to an anode electrode of the first light-emitting element when turned on in response to a third control signal applied to a gate electrode of the third switch transistor.

4. The pixel circuit of claim 1, wherein the driving transistor includes a first electrode connected to a first node, a gate electrode connected to a second node, and a second electrode connected to a third node.

5. The pixel circuit of claim 4, further comprising:
a first switch transistor including a first electrode connected to a fourth node, a gate electrode to which a first control signal is applied, and a second electrode connected to an anode electrode of the first light-emitting element;
a second switch transistor including a first electrode connected to the fourth node, a gate electrode to which a second control signal is applied, and a second electrode connected to an anode electrode of the second light-emitting element;
a third switch transistor including a first electrode connected to the third node, a gate electrode to which an emission signal is applied, and a second electrode connected to the fourth node;
a fourth switch transistor including a first electrode connected to a data line to which a data voltage is applied, a gate electrode to which a first scan signal is applied, and a second electrode connected to a fifth node;
a fifth switch transistor including a first electrode connected to the second node, a gate electrode to which the first scan signal is applied, and a second electrode connected to the third node;
a sixth switch transistor including a first electrode connected to the fifth node, a gate electrode to which the emission signal is applied, and a second electrode to which a reference voltage is applied;
a seventh switch transistor including a first electrode connected to the second node, a gate electrode to which a second scan signal is applied, and a second electrode to which the reference voltage is applied;
an eighth switch transistor including a first electrode connected to the data line, a gate electrode to which the second scan signal is applied, and a second electrode connected to the fifth node; and
a capacitor connected to the second node and the fifth node,
wherein the first light-emitting element includes an anode electrode connected to the second electrode of the first switch transistor and a cathode electrode to which a ground voltage is applied, and
wherein the second light-emitting element includes an anode electrode connected to the second electrode of the second switch transistor and a cathode electrode to which the ground voltage is applied.

6. The pixel circuit of claim 4, further comprising:
a first switch transistor including a first electrode connected to a fifth node, a gate electrode to which a first control signal is applied, and a second electrode connected to a cathode electrode of the second light-emitting element;
a second switch transistor including a first electrode connected to a fourth node, a gate electrode to which a second control signal is applied, and a second electrode connected to the fifth node;
a third switch transistor including a first electrode connected to the third node, a gate electrode to which an emission signal is applied, and a second electrode connected to the fourth node;
a fourth switch transistor including a first electrode connected to a data line to which a data voltage is applied, a gate electrode to which a first scan signal is applied, and a second electrode connected to a sixth node;
a fifth switch transistor including a first electrode connected to the second node, a gate electrode to which the first scan signal is applied, and a second electrode connected to the third node;
a sixth switch transistor including a first electrode connected to the sixth node, a gate electrode to which the emission signal is applied, and a second electrode to which a reference voltage is applied;
a seventh switch transistor including a first electrode connected to the second node, a gate electrode to which a second scan signal is applied, and a second electrode to which the reference voltage is applied;
an eighth switch transistor including a first electrode connected to the data line, a gate electrode to which the second scan signal is applied, and a second electrode connected to the sixth node; and
a capacitor connected to the second node and the sixth node,
wherein the first light-emitting element includes an anode electrode connected to the fourth node and a cathode electrode connected to the fifth node, and
wherein the second light-emitting element includes an anode electrode connected to the fifth node and a cathode electrode to which a ground voltage is applied.

7. The pixel circuit of claim 4, further comprising:
a first switch transistor including a first electrode connected to the third node, a gate electrode to which a first control signal is applied, and a second electrode connected to an anode electrode of the first light-emitting element; and
a second switch transistor including a first electrode connected to the third node, a gate electrode to which a second control signal is applied, and a second electrode connected to an anode electrode of the second light-emitting element,
wherein the first light-emitting element includes an anode electrode connected to the second electrode of the first switch transistor and a cathode electrode to which a ground voltage is applied, and
wherein the second light-emitting element includes an anode electrode connected to the second electrode of the second switch transistor and a cathode electrode to which the ground voltage is applied.

8. The pixel circuit of claim 4, further comprising:
a first switch transistor including a first electrode connected to a fourth node, a gate electrode to which a first control signal is applied, and a second electrode connected to a cathode electrode of the second light-emitting element; and
a second switch transistor including a first electrode connected to the third node, a gate electrode to which a second control signal is applied, and a second electrode connected to the fourth node,
wherein the first light-emitting element includes an anode electrode connected to the third node and a cathode electrode connected to the fourth node, and
wherein the second light-emitting element includes an anode electrode connected to the fourth node and a cathode electrode to which a ground voltage is applied.

9. The pixel circuit of claim 4, further comprising:
a first switch transistor including a first electrode to which a pixel driving voltage is applied, a gate electrode to which a first control signal is applied, and a second electrode connected to an anode electrode of the first light-emitting element; and
a second switch transistor including a first electrode to which the pixel driving voltage is applied, a gate electrode to which a second control signal is applied, and a second electrode connected to an anode electrode of the second light-emitting element,
wherein the first light-emitting element includes an anode electrode connected to the second electrode of the first switch transistor and a cathode electrode connected to the first node, and
wherein the second light-emitting element includes an anode electrode connected to the second electrode of the second switch transistor and a cathode electrode connected to the first node.

10. The pixel circuit of claim 9, further comprising:
a first capacitor connected to the second node and a fourth node;
a second capacitor connected to the first node and the second node;
a third switch transistor including a first electrode connected to the third node, a gate electrode to which an emission signal is applied, and a second electrode to which a ground voltage is applied;
a fourth switch transistor including a first electrode connected to a data line to which a data voltage is applied, a gate electrode to which a first scan signal is applied, and a second electrode connected to the fourth node;
a fifth switch transistor including a first electrode connected to the second node, a gate electrode to which the first scan signal is applied, and a second electrode connected to the third node;
a sixth switch transistor including a first electrode connected to the fourth node, a gate electrode to which the emission signal is applied, and a second electrode to which a reference voltage is applied;
a seventh switch transistor including a first electrode connected to the second node, a gate electrode to which a second scan signal is applied, and a second electrode to which the reference voltage is applied;
an eighth switch transistor including a first electrode connected to the data line, a gate electrode to which the second scan signal is applied, and a second electrode connected to the fourth node; and
a ninth switch transistor including a first electrode to which a pixel driving voltage is applied, a gate electrode to which the first scan signal is applied, and a second electrode connected to the first node.

11. The pixel circuit of claim 4, further comprising:
a first switch transistor including a first electrode connected to an anode electrode of the second light-emitting element, a gate electrode to which a first control signal is applied, and a second electrode connected to a cathode electrode of the second light-emitting element; and
a second switch transistor including a first electrode connected to an anode electrode of the first light-emitting element, a gate electrode to which a second control signal is applied, and a second electrode connected to a cathode electrode of the first light-emitting element,
wherein the first light-emitting element and the second light-emitting element are connected in series between a power line to which a pixel driving voltage is applied and the first node.

12. The pixel circuit of claim 11, further comprising:
a first capacitor connected to the second node and a fourth node;
a second capacitor connected to the first node and the second node;
a third switch transistor including a first electrode connected to the third node, a gate electrode to which an emission signal is applied, and a second electrode to which a ground voltage is applied;
a fourth switch transistor including a first electrode connected to a data line to which a data voltage is applied, a gate electrode to which a first scan signal is applied, and a second electrode connected to the fourth node;
a fifth switch transistor including a first electrode connected to the second node, a gate electrode to which the first scan signal is applied, and a second electrode connected to the third node;
a sixth switch transistor including a first electrode connected to the fourth node, a gate electrode to which the emission signal is applied, and a second electrode to which a reference voltage is applied;
a seventh switch transistor including a first electrode connected to the second node, a gate electrode to which a second scan signal is applied, and a second electrode to which the reference voltage is applied;
an eighth switch transistor including a first electrode connected to the data line, a gate electrode to which the second scan signal is applied, and a second electrode connected to the fourth node; and
a ninth switch transistor including a first electrode to which a pixel driving voltage is applied, a gate electrode to which the first scan signal is applied, and a second electrode connected to the first node.

13. The pixel circuit of claim 5 wherein:
one frame period includes a first period, a second period set after the first period, a third period set after the second period, and a fourth period set after the third period;
during the first period, a voltage of the second scan signal is a gate-on voltage and a voltage of the first scan signal and a voltage of the emission signal are a gate-off voltage;
during the second period, the voltage of the first scan signal is the gate-on voltage and the voltages of the second scan signal and the emission signal are the gate-off voltage;
during the third period, the voltages of the first scan signal, the second scan signal, and the emission signal are the gate-off voltage;
during the fourth period, the voltage of the emission signal is the gate-on voltage and the voltages of the first scan signal and the second scan signal are the gate-off voltage; and
each of the first switch transistor to the eighth switch transistor is turned on in response to the gate-on voltage and is turned off in response to the gate-off voltage.

14. The pixel circuit of claim 4, further comprising:
a first switch transistor including a first electrode connected to the third node, a gate electrode to which a first control signal is applied, and a second electrode connected to an anode electrode of the first light-emitting element;
a second switch transistor including a first electrode connected to the third node, a gate electrode to which a second control signal is applied, and a second electrode connected to an anode electrode of the second light-emitting element;
a third switch transistor including a first electrode connected to a data line to which a data voltage is applied, a gate electrode to which a first scan signal is applied, and a second electrode connected to the second node; and
a fourth switch transistor including a first electrode connected to the third node, a gate electrode to which a second scan signal is applied, and a second electrode connected to a sensing line,
wherein the first light-emitting element includes an anode electrode connected to the second electrode of the first switch transistor and a cathode electrode to which a ground voltage is applied, and
wherein the second light-emitting element includes an anode electrode connected to the second electrode of the second switch transistor and a cathode electrode to which the ground voltage is applied.

15. The pixel circuit of claim 4, further comprising:
a first switch transistor including a first electrode connected to an anode electrode of the second light-emitting element, a gate electrode to which a first control signal is applied and a second electrode connected to a cathode electrode of the second light-emitting element;
a second switch transistor including a first electrode connected to an anode electrode of the first light-emitting element, a gate electrode to which a second control signal is applied and a second electrode connected to a cathode electrode of the first light-emitting element;
a third switch transistor including a first electrode connected to a data line to which a data voltage is applied, a gate electrode to which a first scan signal is applied, and a second electrode connected to the second node; and
a fourth switch transistor including a first electrode connected to the third node, a gate electrode to which a second scan signal is applied and a second electrode connected to a sensing line,
wherein the first light-emitting element includes an anode electrode connected to the third node and a cathode electrode connected to a fourth node, and
wherein the second light-emitting element includes an anode electrode connected to the fourth node and a cathode electrode connected to a power line to which a ground voltage is applied.

16. The pixel circuit of claim 2, wherein voltages of the first control signal and the second control signal are alternately inverted in a periodicity of N (N is a natural number) frame periods or alternately inverted during an emission period within one frame period.

17. The pixel circuit of claim 2, wherein voltages of the first control signal and the second control signal are alternately inverted in a periodicity of one frame period.

18. A display device comprising:
a display panel including a plurality of data lines, a plurality of gate lines, and a plurality of pixel circuits;
a data driving circuit connected to the plurality of data lines; and
a gate driving circuit connected to the plurality of gate lines,
wherein each of the plurality of pixel circuits includes:
a driving transistor configured to generate a current; and
a first light-emitting element and a second light-emitting element electrically connected in parallel or in series to the driving transistor, and
wherein the first light-emitting element and the second light-emitting element are alternately driven by the current from the driving transistor.
